(19) United States
(12) Patent Application Publication
(10) Pub. No.: US 2025/0015105 A1
(43) Pub. Date: Jan. 9, 2025

(54) SUBSTRATE LAMINATE, IMAGE SENSOR, AND METHOD FOR MANUFACTURING SUSTRATE LAMINATE

(71) Applicant: KANEKA CORPORATION, Osaka-shi, Osaka (JP)

(72) Inventors: Ayumu OGAWA, Settsu-shi (JP); Kenta KURODA, Settsu-shi (JP); Daiki KINOSHITA, Settsu-shi (JP); Yuta SAITO, Settsu-shi (JP)

(21) Appl. No.: 18/291,646

(22) PCT Filed: Jul. 28, 2022
(86) PCT No.: PCT/JP2022/029177

§ 371 Date: Sep. 13, 2024

(30) Foreign Application Priority Data
Jul. 30, 2021 (JP) 2021-126296

(51) Int. Cl. H01L 27/146; B32B 3/26; B32B 9/00; B32B 17/06; B32B 37/12; B32B 37/24; G03F 7/00

(52) U.S. Cl. CPC H01L 27/14618; B32B 3/26; B32B 9/005; B32B 17/06; B32B 37/12; B32B 37/24; G03F 7/0035; H01L 27/14683; B32B 2037/243; B32B 2255/26; B32B 2307/202; B32B 2307/306; B32B 2307/40; B32B 2307/406; B32B 2307/542; B32B 2307/7376; B32B 2310/0806; B32B 2313/00; B32B 2315/08; B32B 2551/00

(57) ABSTRACT

A substrate laminate (10) includes a first substrate (11), a second substrate (12), and a cured product layer (13) interposed between the first substrate (11) and the second substrate (12). The cured product layer (13) is patterned, and includes a first layer (14) including a cured product of a first developable composition, and a second layer (15) including a cured product of a second developable composition, in this order from a first substrate (11) side. The first developable composition contains a polymerizable first curable compound and a first photopolymerization initiator and is free of a colorant. The second developable composition contains a polymerizable second curable compound, a second photopolymerization initiator, and a colorant.

### TECHNICAL FIELD

The present invention relates to a substrate laminate, an image sensor, and a method for manufacturing a substrate laminate.

### BACKGROUND ART

Image sensors such as CMOS sensors and CCD sensors are used in digital cameras, smartphones, and the like, and in recent years, the image sensors have been increasingly used and increasingly required to have a smaller size and higher definition along with the popularization of monitoring cameras in automobiles and factories.

A substrate laminate forming the image sensor has, for example, a hollow structure in which a semiconductor element substrate having a light receiving element and a glass substrate are bonded to each other with a patterned layer interposed therebetween. A substrate laminate having a hollow structure is obtained by, for example, the following procedure.

First, a photosensitive composition is applied to one surface of a first substrate (for example, a glass substrate) to form a coating film on the first substrate. Subsequently, the coating film is irradiated with light through a photomask to form an exposed portion formed of the photosensitive composition in a semi-cured state and a non-exposed portion in the coating film. Subsequently, the non-exposed portion is removed from the first substrate with a developer to form a patterned coating film in a semi-cured state (hereinafter, sometimes referred to as a “pattern film”) on the first substrate. Subsequently, the first substrate on which the pattern film is formed and a second substrate (for example, a semiconductor element substrate) are bonded to each other with the pattern film interposed therebetween, and the pattern film is cured to bond the first substrate and the second substrate. A substrate laminate having a hollow structure is obtained through the process described above.

If downsizing of image sensors proceeds, reflected light and scattered light at an end portion of a substrate laminate may enter an imaging area in a hollow structure during imaging, thus causing imaging errors such as flare and ghost. For solving the problem, a method is employed in which a light-shielding film is formed on a glass substrate to inhibit the reflected light and scattered light from entering the imaging area in the hollow structure. As a method for forming a light-shielding film, a metal vapor deposition method is common, but the metal vapor deposition method is costly. A light-shielding film prepared using an inexpensive black resin has been reported (see, for example, Patent Document 1).

### PRIOR ART DOCUMENT

### Patent Document

Patent Document 1: U.S. patent Ser. No. 10/312,276

### SUMMARY OF THE INVENTION

### Problems to be Solved by the Invention

As a method for forming a light-shielding film using a black resin, photolithography that enables fine processing is employed for the purpose of improving dimension accuracy. However, studies by the present inventors have revealed that formation of a light-shielding film by photolithography using a black resin often causes a problem in which foreign matter derived from a colorant in the black resin remains on an imaging surface. The foreign matter may cause an imaging error such as reflection during imaging.

The present invention has been made in view of the above-described problems, and an object of the present invention is to provide a substrate laminate resistant to deposition of foreign matter derived from a colorant, a method for manufacturing the substrate laminate, and an image sensor including the substrate laminate.

### Means for Solving the Problems

### <Aspects of the Invention>

An aspect of the present invention is as follows.

[1] A method for manufacturing a substrate laminate, including:
a step Sa of forming a coating film on a first substrate;
a step Sb of forming an exposed portion in a semi-cured state and a non-exposed portion on the first substrate by irradiating the coating film with an active energy ray through a photomask;
a step Sc of forming a patterned coating film on the first substrate by removing the non-exposed portion from the first substrate with a developer; and
a step Sd1 of bonding the first substrate and a second substrate with the patterned coating film interposed therebetween, in which
the exposed portion in the semi-cured state includes a first semi-cured layer formed of a first developable composition in a semi-cured state and a second semi-cured layer formed of a second developable composition in a semi-cured state, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

[2] The method for manufacturing a substrate laminate according to [1], in which the second substrate includes a semiconductor element substrate and a frame member, and
the first substrate and the frame member are bonded with the patterned coating film interposed therebetween in the step Sd1.

[3] The method for manufacturing a substrate laminate according to [1] or [2], in which in the step Sd1, the patterned coating film is heated to further cure the first developable composition in the semi-cured state and the second developable composition in the semi-cured state, and the cured coating film and the second substrate are then bonded with an adhesive.

[4] The method for manufacturing a substrate laminate according to [1] or [2], in which in the step Sd1, a laminated product is formed by laminating the first substrate and the second substrate with the coating film, which is patterned in a semi-cured state, interposed therebetween, and the first substrate and the second substrate are then bonded by heating the laminated product to further cure the coating film.

[5] A method for manufacturing a substrate laminate, including:
a step Sa of forming a coating film on a first substrate;
a step Sb of forming an exposed portion in a semi-cured state and a non-exposed portion on the first substrate by irradiating the coating film with an active energy ray through a photomask;
a step Sc of forming a patterned coating film on the first substrate by removing the non-exposed portion from the first substrate with a developer; and
a step Sd2 of bonding a surface of the first substrate on a side opposite to a surface on which the patterned coating film is formed and a second substrate with an adhesive, in which
the exposed portion in the semi-cured state includes a first semi-cured layer formed of a first developable composition in a semi-cured state and a second semi-cured layer formed of a second developable composition in a semi-cured state, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

[6] The method for manufacturing a substrate laminate according to [5], in which the second substrate includes a semiconductor element substrate and a frame member, and
the first substrate and the frame member are bonded with the adhesive in the step Sd2.

[7] The method for manufacturing a substrate laminate according to any one of [1] to [6], in which in the step Sa, the first developable composition is applied onto the first substrate, and the second developable composition is applied onto a first film formed of the first developable composition to form the coating film including the first film and a second film formed of the second developable composition.

[8] The method for manufacturing a substrate laminate according to [7], in which the coating film further includes a third film composed of a third developable composition,
the third developable composition contains a polymerizable third curable compound and a third photopolymerization initiator and is free of a colorant, and
the third developable composition is applied to a surface of the second film on a side opposite to a first film side in the step Sa.

[9] The method for manufacturing a substrate laminate according to any one of [1] to [6], in which in the step Sa, the first developable composition is applied onto the first substrate, a first film composed of the first developable composition is irradiated with an active energy ray, and the second developable composition is applied onto the first film after irradiation with the active energy ray to form the coating film including the first film and a second film formed of the second developable composition.

[10] The method for manufacturing a substrate laminate according to [9], in which the coating film further includes a third film composed of a third developable composition,
the third developable composition contains a polymerizable third curable compound and a third photopolymerization initiator and is free of a colorant, and
the third developable composition is applied to a surface of the second film on a side opposite to a first film side in the step Sa.

[11] The method for manufacturing a substrate laminate according to any one of [1] to [10], in which the first developable composition and the second developable composition are alkali-soluble.

[12] The method for manufacturing a substrate laminate according to any one of [1] to [11], in which the first substrate is a glass substrate.

[13] The method for manufacturing a substrate laminate according to any one of [1] to [12], in which the first curable compound is cationically polymerizable or radically polymerizable.

[14] The method for manufacturing a substrate laminate according to any one of [1] to [13], in which the second curable compound is cationically polymerizable or radically polymerizable.

[15] The method for manufacturing a substrate laminate according to any one of [1] to [14], in which the second photopolymerization initiator is a photocationic polymerization initiator, and the photocationic polymerization initiator has one or more structures selected from the group consisting of a naphthalimide structure and an oxime sulfonate structure.

[16] The method for manufacturing a substrate laminate according to any one of [1] to [15], in which the second developable composition further contains a sensitizer.

[17] A substrate laminate including a first substrate, a second substrate, and a cured product layer interposed between the first substrate and the second substrate, in which
the cured product layer is patterned, and includes a first layer including a cured product of a first developable composition and a second layer including a cured product of a second developable composition, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

[18] The substrate laminate according to [17], further including an adhesive layer that bonds the cured product layer and the second substrate.

[19] A substrate laminate including a first substrate, a second substrate, an adhesive layer that bonds the first substrate and the second substrate, and a cured product layer disposed on a surface of the first substrate on a side opposite to a second substrate side, in which
the cured product layer is patterned, and includes a first layer including a cured product of a first developable composition and a second layer including a cured product of a second developable composition, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

[20] An image sensor including the substrate laminate according to any one of [17] to [19].

### Effect of the Invention

According to the present invention, it is possible to provide a substrate laminate resistant to deposition of foreign matter derived from a colorant, a method for manufacturing the substrate laminate, and an image sensor including the substrate laminate.

### BRIEF DESCRIPTION OF THE DRAWINGS

FIG. 1 is a sectional view showing an example of a substrate laminate according to the present invention.

FIG. 2 is a sectional view showing another example of a substrate laminate according to the present invention.

FIG. 3 is a sectional view showing another example of a substrate laminate according to the present invention.

FIG. 4 is a sectional view showing another example of a substrate laminate according to the present invention.

FIG. 5 is a sectional view showing another example of a substrate laminate according to the present invention.

FIG. 6 is a sectional view showing another example of a substrate laminate according to the present invention.

FIG. 7 is a sectional view showing another example of a substrate laminate according to the present invention.

FIG. 8 is a sectional view showing another example of a substrate laminate according to the present invention.

FIG. 9 is a plan view showing a first substrate after formation of a cured product layer in manufacture of an example of a substrate laminate according to the present invention.

FIG. 10 is a plan view showing a first substrate after formation of a cured product layer and after singulation in manufacture of an example of a substrate laminate according to the present invention.

FIGS. 11A, 11B, and 11C are step-by-step sectional views showing an example of a method for manufacturing a substrate laminate according to the present invention.

FIGS. 12A, 12B, and 12C are step-by-step sectional views showing an example of a method for manufacturing a substrate laminate according to the present invention.

FIGS. 13A, 13B, and 13C are step-by-step sectional views showing an example of a method for manufacturing a substrate laminate according to the present invention.

FIGS. 14A, 14B, and 14C are step-by-step sectional views showing another example of a method for manufacturing a substrate laminate according to the present invention.

FIGS. 15A, 15B, and 15C are step-by-step sectional views showing another example of a method for manufacturing a substrate laminate according to the present invention.

### MODE FOR CARRYING OUT THE INVENTION

Preferred embodiments of the present invention will be described in detail below, but the present invention is not limited to these embodiments. The academic documents and patent documents mentioned herein are incorporated herein by reference in their entirety.

First, terms used herein will be described. The term “photopolymerization initiator” refers to a compound that generates an active species (specifically, radical, cation, anion, or the like) when irradiated with an active energy ray. The term “photocationic polymerization initiator” refers to a compound that generates a cation (acid) as an active species when irradiated with an active energy ray. The term “photoradical polymerization initiator” refers to a compound that generates a radical as an active species when irradiated with an active energy ray. Examples of the active energy ray include visible light rays, ultraviolet rays, infrared rays, electron beams, X-rays, α-rays, β-rays, and γ-rays.

The term “cationically polymerizable group” refers to a functional group that causes a polymerization reaction in a chain reaction in the presence of a cation. The term “radically polymerizable group” refers to a functional group having a radically polymerizable unsaturated bond. The term “alkali-soluble group” refers to a functional group that enhances solubility in an alkaline solution by interacting with an alkali or reacting with an alkali. The term “developable composition” refers to a composition containing one or more selected from the group consisting of a compound having an alkali-soluble group and a compound soluble in an organic solvent. The phrase “a developable composition has alkali-solubility” means that the developable composition contains a compound having an alkali-soluble group. The phrase “a developable composition has organic solvent-solubility” means that the developable composition contains a compound soluble in an organic solvent. The term “sensitizer” refers to a compound that improves the exposure sensitivity. The term “alicyclic epoxy group” refers to a functional group formed by bonding one oxygen atom to two adjacent carbon atoms among carbon atoms forming an alicyclic structure, and examples thereof include a 3,4-epoxycyclohexyl group. The “polysiloxane compound” is a compound having a polysiloxane structure having a siloxane unit (Si—O—Si) as a constituent element. Examples of the polysiloxane structure include chain polysiloxane structures (specifically, linear polysiloxane structures, branched polysiloxane structures and the like) and cyclic polysiloxane structures. The term “epoxy-based adhesive” refers to an adhesive containing a compound having an epoxy group (for example, a compound containing at least two epoxy groups in one molecule) as a main agent. The term “semi-cured state” refers to a state in which the degree of curing can be further increased by a subsequent step (for example, a heating step). The term “solid content” is a nonvolatile component in the composition, and the term “total solid content” means the total amount of composition constituent components excluding solvents.

The “thickness” of each layer forming the substrate laminate is represented by an arithmetic average of ten measured values obtained by selecting ten measurement locations at random from an electron microscope image of a cross-section of the substrate laminate cut in a thickness direction, and measuring thicknesses at the ten selected measurement locations.

Unless otherwise specified, the term “main component” of a material means a component contained in the material in the largest amount on a mass basis.

The “alkyl group,” the “alkenyl group,” the “alkynyl group,” the “alkoxy group,” the “acyl group,” the “alkylthio group,” and the “halogenated alkyl group” may be linear or branched. Examples of the “halogen atom” include a fluorine atom, a chlorine atom, a bromine atom, and an iodine atom. The phrase “the organic group (more specifically, an aryl group or the like) may be substituted with a substituent (more specifically, an alkyl group or the like)” means that some or all of hydrogen atoms of the organic group may be substituted with substituents.

Hereinafter, the name of a compound may be followed by the term “-based” to collectively refer to the compound and derivatives thereof. The term “-based” following the name of a compound to express the name of a polymer means that repeating units of the polymer are derived from the compound or a derivative thereof. Acryl and methacryl may be collectively referred to as “(meth)acryl.” Acrylate and methacrylate may be collectively referred to as “(meth)acrylate.” Acryloyl and methacryloyl may be collectively referred to as “(meth)acryloyl.”

Unless otherwise specified, one of the components, functional groups and the like shown in the present description may be used alone, or two or more thereof may be used in combination.

In the drawings that are referred to in the following description, mainly relevant components are schematically shown for easy understanding, and the size, the number, the shape, and the like of each illustrated component may be different from the actual counterparts for convenience of preparing the drawings. For convenience of description, there may be cases where in the drawings that are described later, the same component parts as those in the drawings described previously are given the same symbols, and descriptions thereof are omitted.

### First Embodiment: Substrate Laminate

A substrate laminate (hereinafter, sometimes referred to as a “substrate laminate L1”) according to a first embodiment of the present invention includes a first substrate, a second substrate, and a cured product layer interposed between the first substrate and the second substrate. The cured product layer is patterned, and includes a first layer including a cured product of a first developable composition, and a second layer including a cured product of a second developable composition, in this order from a first substrate side. The first developable composition contains a polymerizable first curable compound and a first photopolymerization initiator and is free of a colorant. The second developable composition contains a polymerizable second curable compound, a second photopolymerization initiator, and a colorant.

In the present specification, the phrase “the first developable composition is free of a colorant” means that the amount of the colorant in the first layer including a cured product of the first developable composition is less than 0.1 parts by mass (preferably less than 0.01 parts by mass, more preferably less than 0.001 parts by mass, still more preferably less than 0.0001 parts by mass) based on 100 parts by mass of the colorant in the second layer including a cured product of the second developable composition.

The substrate laminate L1 is resistant to deposition of foreign matter derived from a colorant. The reason for this is presumed as follows.

The substrate laminate L1 can be manufactured by a manufacture method according to a third embodiment described later. Thus, in manufacture of the substrate laminate L1, a first film formed of the first developable composition free of a colorant can be formed on the first substrate, followed by formation of a second film formed of the second developable composition containing a colorant on the first film. This enables suppression of contact between the second developable composition containing a colorant and the first substrate. Further, in a step Sc in a manufacturing method according to the third embodiment described later, a second non-exposed layer formed of the second developable composition containing a colorant can be removed, followed by removal of a first non-exposed layer composed of the first developable composition free of a colorant, so that it is possible to suppress the remaining of the colorant between patterns during development. Therefore, the substrate laminate L1 is resistant to deposition of foreign matter derived from a colorant.

### [Configuration of Substrate Laminate L1]

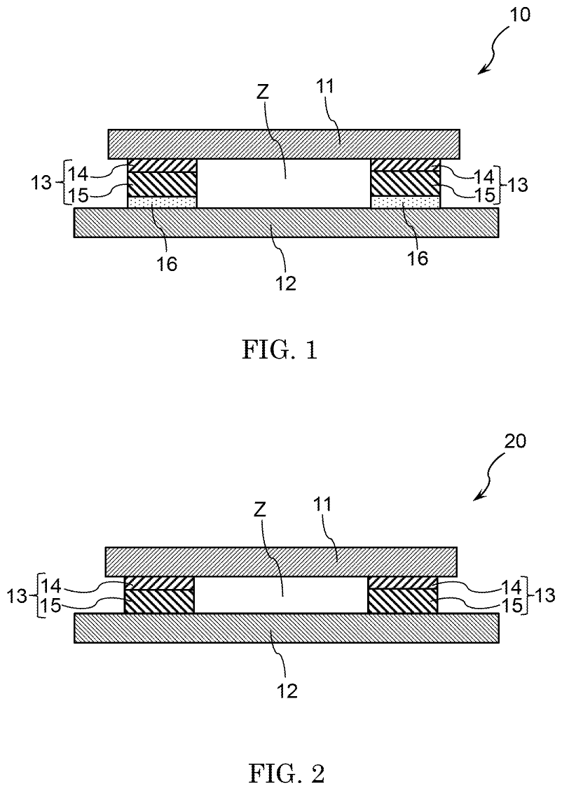

Hereinafter, an example of a configuration of the substrate laminate L1 will be described with reference to the drawings as appropriate. FIG. 1 is a sectional view showing an example of the substrate laminate L1. A substrate laminate 10 shown in FIG. 1 includes a first substrate 11, a second substrate 12, and a cured product layer 13 interposed between the first substrate 11 and the second substrate 12. The cured product layer 13 is patterned, and includes a first layer 14 including a cured product of the first developable composition, and a second layer 15 including a cured product of the second developable composition, in this order from the first substrate 11 side. The first developable composition contains a polymerizable first curable compound and a first photopolymerization initiator and is free of a colorant. The second developable composition contains a polymerizable second curable compound, a second photopolymerization initiator, and a colorant.

The substrate laminate 10 further includes an adhesive layer 16 that bonds the cured product layer 13 and the second substrate 12. In the example shown in FIG. 1, the second layer 15 and the second substrate 12 are bonded by the adhesive layer 16. The substrate laminate 10 including the adhesive layer 16 is resistant to ingress of foreign matter into a hollow portion Z surrounded by the first substrate 11, the second substrate 12, the cured product layer 13 and the adhesive layer 16. The reason for this is presumed as follows.

In manufacturing the substrate laminate 10, the first developable composition in a semi-cured state and the second developable composition in a semi-cured state can be further cured, followed by bonding of the coating film after curing (cured coating film) and the second substrate 12 to each other with an adhesive, in a step Sd1 described later. As compared to a coating film in a semi-cured state, the above-described cured coating film has a lower tackiness, so that foreign matter is less likely to be deposited on the coating film. Thus, the substrate laminate 10 is resistant to ingress of foreign matter into the hollow portion Z in bonding of the first substrate 11 and the second substrate 12 to each other.

In the substrate laminate 10, the second layer 15 includes a cured product of the second developable composition containing a colorant. Thus, the second layer 15 can be used as, for example, a light-shielding partition wall for suppressing flare and ghost. When the second layer 15 is used as a light-shielding partition wall, for example, the cured product layer 13 and the adhesive layer 16 are provided so as to surround a light receiving element provided on the second substrate 12 (not shown).

The interface between the first layer 14 and the second layer 15 may be clearly identifiable, or may be unable to be clearly identified. When the interface between the first layer 14 and the second layer 15 cannot be clearly identified, an intermediate layer including a mix of a cured product of the first developable composition and a cured product of the second developable composition (not shown) may be present between the first layer 14 and the second layer 15. In this case, the cured product layer 13 includes the first layer 14, the intermediate layer, and the second layer 15.

In the substrate laminate 10, the hollow portion Z may be a sealed space. When the substrate laminate 10 forms an image sensor, and the hollow portion Z is a sealed space, the cured product layer 13 and the adhesive layer 16 function as a partition wall that prevents ingress of moisture and dust into effective pixel regions. In the substrate laminate 10 shown in FIG. 1, the width of the cured product layer 13 (the length in the horizontal direction in FIG. 1) and the width of the adhesive layer 16 are substantially equal to each other, but in the present invention, the width of the cured product layer and the width of the adhesive layer may be different from each other.

As an index of the light shielding property of the second layer 15, the light transmittance of the second layer 15 can be used. When the thickness of the second layer 15 is 50 μm, the maximum light transmittance of the second layer 15 at a wavelength of 300 to 400 nm is preferably 15% or less, more preferably 10% or less, still more preferably 0.1% or less, form the viewpoint of suppressing flare. Also, when the thickness of the second layer 15 is 50 μm, the optical density (OD) of the second layer 15 is preferably 0.8 or more, more preferably 1.0 or more, still more preferably 3.0 or more, from the viewpoint of suppressing flare. The maximum light transmittance of the second layer 15 at a wavelength of 300 to 400 nm and the optical density of the second layer 15 can be adjusted by, for example, changing the amount of the colorant in the second layer 15.

### [Elements of Substrate Laminate L1]

Next, elements of the substrate laminate L1 will be described.

### (First Substrate 11 and Second Substrate 12)

Examples of the first substrate 11 and the second substrate 12 include silicon wafers, glass substrates, resin substrates (transparent resin substrates and the like), ceramic substrates, and semiconductor element substrates. Examples of the semiconductor element substrate include sensor substrates (more specifically, image sensor substrates and the like). The types of the first substrate 11 and the second substrate 12 may be the same or different. When one of the first substrate 11 and the second substrate 12 is a transparent substrate (more specifically, a glass substrate, a transparent resin substrate or the like), the substrate laminate L1 can be applied to a constituent member of an optical component. In particular, the substrate laminate L1 in which one of the first substrate 11 and the second substrate 12 is a transparent substrate and the other is a semiconductor element substrate is suitable for image sensors.

When a glass substrate is used as the first substrate 11, deposition of foreign matter derived from the colorant on the glass substrate can be suppressed. This enables suppression of reflection of foreign matter during imaging in application of the substrate laminate L1 to an image sensor.

The thickness of each of the first substrate 11 and the second substrate 12 is, for example, 50 μm or more and 2,000 μm or less. When one of the first substrate 11 and the second substrate 12 is a semiconductor element substrate, the thickness of the semiconductor element substrate is, for example, 50 μm or more and 800 μm or less. The thickness of the first substrate 11 and the thickness of the second substrate 12 may be the same or different.

### (First Layer 14)

The first layer 14 includes a cured product of the first developable composition. Details of the first developable composition as a material for the first layer 14 will be described later. The thickness (height) of the first layer 14 is, for example, 0.001 μm or more and 100 μm or less. For further suppressing deposition of foreign matter derived from a colorant, the thickness of the first layer 14 is preferably 0.005 μm or more, more preferably 0.01 μm or more, still more preferably 0.1 μm or more, even more preferably 1 μm or more, particularly preferably 2 μm or more. For effectively suppressing flare and ghost by using the second layer 15 as a light-shielding partition wall, the thickness of the first layer 14 is preferably 50 μm or less, more preferably 10 μm or less, still more preferably 9 μm or less, even more preferably 8 μm or less, particularly preferably 7 μm or less, and may be 6 μm or less or 5 μm or less.

The width of the first layer 14 is, for example, 10 μm or more and 500 μm or less, preferably 10 μm or more and 200 μm or less, more preferably 20 μm or more and 150 μm or less.

### (Second Layer 15)

The second layer 15 includes a cured product of the second developable composition. Details of the second developable composition as a material for the second layer 15 will be described later. The thickness (height) of the second layer 15 is, for example, 0.01 μm or more and 100 μm or less. For effectively suppressing flare and ghost by using the second layer 15 as a light-shielding partition wall, the thickness of the second layer 15 is preferably 0.1 μm or more, more preferably 5 μm or more, still more preferably 10 μm or more, even more preferably 15 μm or more, particularly preferably 20 μm or more. From the viewpoint of ease of patterning of the second layer 15, the thickness of the second layer 15 is preferably 50 μm or less, more preferably 40 μm or less, still more preferably 30 μm or less. The second developable composition as a material for the second layer 15 contains a colorant, and when the thickness of the second layer 15 is 50 μm or less, the second layer 15 can be formed without hindering the patterning property.

The width of the second layer 15 is, for example, 10 μm or more and 500 μm or less, preferably 10 μm or more and 200 μm or less, more preferably 20 μm or more and 150 μm or less.

### (Adhesive Layer 16)

The adhesive layer 16 includes a cured product of an adhesive. Examples of the adhesive as a material for the adhesive layer 16 include thermosetting adhesives (more specifically, epoxy-based adhesives and the like), and ultraviolet-curable adhesives (More specifically, acryl-based adhesives and the like). The term “acryl-based adhesive” means an adhesive containing (meth)acrylic acid or a derivative thereof (more specifically, (meth)acrylic acid ester or the like) or a polymer of (meth)acrylic acid or a derivative thereof as a main component.

For obtaining the substrate laminate L1 further excellent in adhesiveness between substrates, the adhesive as a material for the adhesive layer 16 is preferably an epoxy-based adhesive. When an epoxy-based adhesive is used as the adhesive as a material for the adhesive layer 16, the main agent of the epoxy-based adhesive is preferably an aromatic epoxy compound having two or more epoxy groups, more preferably a bisphenol-based diglycidyl ether (more specifically, bisphenol A diglycidyl ether, bisphenol F diglycidyl ether, bisphenol S diglycidyl ether, or the like), still more preferably bisphenol A diglycidyl ether for obtaining the substrate laminate L1 further excellent in adhesiveness between substrates.

When an epoxy-based adhesive is used as the adhesive as a material for the adhesive layer 16, the curing agent for the epoxy-based adhesive is preferably an imidazole-based curing agent for obtaining the substrate laminate L1 further excellent in adhesiveness between substrates.

For obtaining the substrate laminate L1 further excellent in adhesiveness between substrates, the adhesive as a material for the adhesive layer 16 is preferably an epoxy-based adhesive containing bisphenol-based diglycidyl ether as a main agent and an imidazole-based curing agent as a curing agent, more preferably an epoxy-based adhesive containing bisphenol A diglycidyl ether as a main agent and an imidazole-based curing agent as a curing agent. Here, the mass ratio of the main agent to the curing agent (main agent/curing agent) in the epoxy-based adhesive is, for example, 100/10 or more and 100/1 or less.

For obtaining the substrate laminate L1 which is excellent in adhesiveness between substrates and also excellent in reliability evaluated in a thermal shock test, the height (thickness) of the adhesive layer 16 is preferably 0.01 μm or more and 200 μm or less, more preferably 0.1 μm or more and 150 μm or less, still more preferably 1 μm or more and 120 μm or less. The width of the adhesive layer 16 can be appropriately changed according to the width of the second layer 15, and is, for example, 10 μm or more and 500 μm or less, preferably 10 μm or more and 200 μm or less, more preferably 20 μm or more and 150 μm or less. For obtaining the substrate laminate L1 further excellent in reliability evaluated in a thermal shock test, the width of the adhesive layer 16 when the width of the second layer 15 is defined as 100% is preferably 70% or more, more preferably 80% or more, still more preferably 90% or more, and may be 100% or more, 110% or more, or 120% or more.

### [First Developable Composition]

Next, the first developable composition as a material for the first layer 14 will be described. The first developable composition contains a polymerizable first curable compound and a first photopolymerization initiator and is free of a colorant. The first developable composition may contain components other than the first curable compound and the first photopolymerization initiator (other components). For obtaining the substrate laminate L1 which is excellent in adhesiveness between substrates while having the first layer 14 excellent in heat resistance, the total content ratio of the first curable compound and the first photopolymerization initiator is preferably 50 mass % or more, more preferably 60 mass % or more, still more preferably 70 mass % or more, even more preferably 80 mass % or more and 100 mass % or less, based on the total solid content of the first developable composition.

Examples of the other component include a reactive diluent, a crosslinker, a basic compound, a sensitizer, an adhesiveness improver, a thermoplastic resin, a filler, an antioxidant, a radical inhibitor, a polymer dispersant, a mold release agent, a flame retardant, a flame retardant promoter, a surfactant, an antifoaming agent, an emulsifier, a leveling agent, a cissing inhibitor, an ion trapping agent (antimony-bismuth or the like), a thixotropy imparting agent, a tackifier, a storage stability improver, an ozone degradation inhibitor, a light stabilizer, a thickener, a plasticizer, a heat stabilizer, a conductivity imparting agent, an antistatic agent, a radiation blocking agent, a nucleating agent, a phosphorus-based peroxide decomposer, a lubricant, a metal deactivator, a thermal conductivity imparting agent, a physical property modifier, and a solvent.

The first curable compound is, for example, cationically polymerizable and/or radically polymerizable. That is, the first curable compound has, for example, one or more groups selected from the group consisting of a cationically polymerizable group and a radically polymerizable group (hereinafter, sometimes referred to as a “polymerizable group”). For obtaining the substrate laminate L1 excellent in adhesiveness between substrates, the first curable compound has preferably a cationically polymerizable group, more preferably both a cationically polymerizable group and a radically polymerizable group.

Preferably, the first curable compound has a plurality of polymerizable groups in one molecule. When the first curable compound has a plurality of polymerizable groups in one molecule, the crosslinking density of the first layer 14 tends to increase, resulting in improvement of the heat resistance of the first layer 14. A plurality of polymerizable groups may be the same, or two or more different functional groups. The first developable composition may contain only one first curable compound, or a plurality of first curable compounds.

The first developable composition may have both a first curable compound having a cationically polymerizable group and a first curable compound having a radically polymerizable group.

Examples of the cationically polymerizable group include an epoxy group, a vinyl ether group, an oxetanyl group, and an alkoxysilyl group. From the viewpoint of the storage stability of the first developable composition, the cationically polymerizable group is preferably one or more selected from the group consisting of a glycidyl group, an alicyclic epoxy group and an oxetanyl group, more preferably one or more selected from the group consisting of a glycidyl group and an alicyclic epoxy group. Among them, an alicyclic epoxy group is particularly preferable because it is excellent in photocationic polymerizability.

When the first developable composition contains a first curable compound having one or more selected from the group consisting of a glycidyl group and an alicyclic epoxy group, the first substrate 11 is preferably a glass substrate. Since both a glycidyl group and an alicyclic epoxy group have good bondability to a surface of the glass substrate, it is possible to obtain the substrate laminate L1 further excellent in adhesiveness between substrates when the first developable composition contains a first curable compound having one or more selected from the group consisting of a glycidyl group and an alicyclic epoxy group, and the first substrate 11 is a glass substrate.

When the first developable composition contains a first curable compound having one or more selected from the group consisting of a glycidyl group and an alicyclic epoxy group, it is preferable to use an epoxy-based adhesive as an adhesive as a material of the adhesive layer 16 for obtaining the substrate laminate L1 further excellent in adhesiveness between substrates.

Examples of the first curable compound having a cationically polymerizable group include polysiloxane compounds having a cationically polymerizable group, bisphenol A type epoxy resins, hydrogenated bisphenol A type epoxy resins, novolac phenol type epoxy resins, biphenyl type epoxy resins, dicyclopentadiene type epoxy resins, bisphenol F diglycidyl ether, bisphenol A diglycidyl ether, 2,2′-bis(4-glycidyloxycyclohexyl)propane, vinylcyclohexene dioxide, 2-(3,4-epoxycyclohexyl)-5,5-spiro-(3,4-epoxycyclohexane)-1,3-dioxane, bis(3,4-epoxycyclohexyl)adipate, 1,2-cyclopropanedicarboxylic acid bisglycidyl esters, triglycidyl isocyanurate, monoallyl diglycidyl isocyanurate, diallyl monoglycidyl isocyanurate, 3-ethyl-3-(phenoxymethyl)oxetane, di-2-ethylhexyl 4,5-epoxycyclohexane-1,2-dicarboxylate (“SANSO CIZER (registered trademark) E-PS” manufactured by New Japan Chemical Co., Ltd.), 3′,4′-epoxycyclohexylmethyl 3,4-epoxycyclohexanecarboxylate (“CELLOXIDE (registered trademark) 2021 P” manufactured by DAICEL CORPORATION), and F-caprolactone-modified 3′,4′-epoxycyclohexylmethyl 3,4-epoxycyclohexanecarboxylate (“CELLOXIDE (registered trademark) 2081” manufactured by DAICEL CORPORATION).

When a curable compound having one cationically polymerizable group in one molecule (for example, di-2-ethylhexyl 4,5-epoxycyclohexane-1,2-dicarboxylate or the like) is used as the first curable compound, the crosslinking density decreases, resulting in enhancement of the flexibility of the first layer 14. Thus, for obtaining the substrate laminate L1 excellent in reliability evaluated in a thermal shock test, the first developable composition contains, as the first curable compound, preferably a curable compound having one cationically polymerizable group in one molecule, more preferably a curable compound having one alicyclic epoxy group in one molecule.

Examples of the radically polymerizable group include an acryloyl group and a methacryloyl group. The first curable compound may have only one or both of an acryloyl group and a methacryloyl group as the radically polymerizable group. Among them, the acryloyl group is particularly preferable because it is highly photoradically polymerizable.

Examples of the first curable compound having a radically polymerizable group include polysiloxane compounds having a radically polymerizable group, isoamyl acrylate, lauryl acrylate, octyl acrylate, decyl acrylate, isostearyl acrylate, butoxyethyl (meth)acrylate, ethoxydiethylene glycol acrylate, methoxydiethylene glycol acrylate, methoxytripropylene glycol acrylate, methoxypolyethylene glycol acrylate, phenoxyethyl acrylate, tetrahydrofurfuryl (meth)acrylate, triethylene glycol di(meth)acrylate, tetraethylene glycol di(meth)acrylate, polyethylene glycol di(meth)acrylate, tripropylene glycol di(meth)acrylate, polypropylene glycol di(meth)acrylate (more specifically, polypropylene glycol #700 diacrylate and the like), 1,6-hexanediol di(meth)acrylate, 1,9-nonanediol di(meth)acrylate, neopentyl glycol di(meth)acrylate, polytetramethylene glycol di(meth)acrylate, trimethylolpropane tri(meth)acrylate, pentaerythritol tri(meth)acrylate, glycerinpropoxy tri(meth)acrylate, pentaerythritol tetra(meth)acrylate, and ditrimethylolpropane tetra(meth)acrylate.

The first developable composition contains one or more selected from the group consisting of a compound having an alkali-soluble group and a compound soluble in an organic solvent. Examples of the compound having an alkali-soluble group include polysiloxane compounds having an alkali-soluble group, resins having a phenolic hydroxyl group (for example, novolac-based resins having a phenolic hydroxyl group), resins having a carboxy group (for example, copolymers of (meth)acrylic acid and (meth)acrylic acid ester), and epoxy acrylate-based compounds having an acidic group. The compound soluble in an organic solvent is not particularly limited, and examples thereof include a component (A) described later. Since the use of an alkaline developer as a developer tends to lead to a superior patterning property as compared to the use of an organic solvent developer in patterning, it is preferable that the first developable composition contains a compound having an alkali-soluble group. The first developable composition may have alkali solubility and organic solvent solubility.

For enhancing the heat resistance of the first layer 14 while improving the patterning property, and enhancing adhesion between substrates and reliability in a thermal shock test, it is preferable that the first developable composition contains, as the first curable compound, a polysiloxane compound having a polymerizable group and an alkali-soluble group in one molecule (hereinafter, sometimes referred to as a “component (A)”).

The component (A) is not particularly limited as long as it is a polysiloxane compound having a polymerizable group (one or more groups selected from the group consisting of a cationically polymerizable group and a radically polymerizable group) and an alkali-soluble group in one molecule. Preferably, the component (A) has a plurality of polymerizable groups in one molecule. When the component (A) has a plurality of polymerizable groups in one molecule, the crosslinking density of the first layer 14 tends to increase, resulting in further improvement of the heat resistance of the first layer 14. A plurality of polymerizable groups may be the same, or two or more different functional groups. Preferably, the component (A) has a plurality of alkali-soluble groups in one molecule. When the component (A) has a plurality of alkali-soluble groups in one molecule, developability tends to be further improved because non-exposed portion removability is enhanced during development. A plurality of alkali-soluble groups may be the same, or two or more different functional groups.

The component (A) may have a chain polysiloxane structure or a cyclic polysiloxane structure. For forming the first layer 14 having further excellent heat resistance, it is preferable that the component (A) has a cyclic polysiloxane structure. When the component (A) has a cyclic polysiloxane structure, the first developable composition tends to have high film formability and developability.

The component (A) may have a polysiloxane structure in the main chain or a polysiloxane structure in the side chain. For forming the first layer 14 having further excellent heat resistance, it is preferable that the component (A) has a polysiloxane structure in the main chain. For forming the first layer 14 having further excellent heat resistance, it is preferable that the component (A) has a cyclic polysiloxane structure in the main chain.

The cyclic polysiloxane structure may be a monocyclic structure or a polycyclic structure. The polycyclic structure may be a polyhedral structure. The first layer 14 having high hardness and excellent heat resistance tends to be obtained when the content ratio of T units (XSiO_{3/2}) or the Q units (SiO_{4/2}) among siloxane units forming a ring is high. The first layer 14 which is more flexible and has reduced residual stress tends to be obtained when the content ratio of M units (X₃SiO_{1/2}) or the D units (X₂SiO_{2/2}) is high.

When the component (A) is a polymer having a polysiloxane structure in the main chain, the weight average molecular weight of the polymer is preferably 10,000 or more and 50,000 or less, more preferably 20,000 or more and 40,000 or less. When the weight average molecular weight is 10,000 or more, the heat resistance of the obtained first layer 14 tends to be further improved. On the other hand, when the weight average molecular weight is 50,000 or less, developability tends to be further improved.

As examples of the polymerizable group of the component (A), those shown above as examples of the polymerizable group (specifically, examples of the cationically polymerizable group and examples of the radically polymerizable group) of the first curable compound are exemplified, and the same applies to preferred examples thereof.

The alkali-soluble group of the component (A) is preferably one or more selected from the group consisting of a monovalent organic group represented by the following chemical formula (X1) (hereinafter, sometimes referred to as an “X1 group”), a divalent organic group represented by the following chemical formula (X2) (hereinafter, sometimes referred to as an “X2 group”), a phenolic hydroxyl group, and a carboxy group. The X1 group is a monovalent organic group derived from a N-mono-substituted isocyanuric acid. The X2 group is a divalent organic group derived from a N,N′-disubstituted isocyanuric acid.

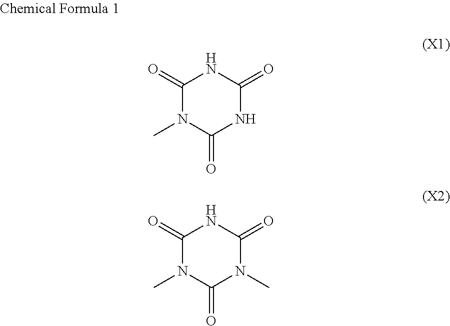

For forming the first layer 14 having further excellent heat resistance, the alkali-soluble group of the component (A) is preferably one or more selected from the group consisting of the X1 group and the X₂ group.

The method for introducing the polymerizable group into the polysiloxane compound is not particularly limited, and a method using a hydrosilylation reaction is preferable because a polymerizable group can be introduced into a polysiloxane compound via a chemically stable silicon-carbon bond (Si—C bond). In other words, the component (A) is preferably a polysiloxane compound which is organically modified by a hydrosilylation reaction and into which a polymerizable group is introduced via a silicon-carbon bond. Preferably, the alkali-soluble group is also introduced into the polysiloxane compound via a silicon-carbon bond by a hydrosilylation reaction.

The component (A) is obtained by, for example, a hydrosilylation reaction using the following compounds (α), (β), and (γ) as starting substances.
Compound (α): a polysiloxane compound having at least two SiH groups (hydrosilyl groups) in one molecule.
Compound (β): a compound having a carbon-carbon double bond having reactivity with a SiH group and a polymerizable group in one molecule.
Compound (γ): a compound having a carbon-carbon double bond having reactivity with a SiH group and an alkali-soluble group in one molecule.

### (Compound (α))

The compound (α) is a polysiloxane compound having at least two SiH groups in one molecule, and it is possible to used, for example, a compound disclosed in WO 96/15194, which has at least two SiH groups in one molecule. Specific examples of the compound (α) include hydrosilyl group-containing polysiloxanes having a linear structure, polysiloxanes having a hydrosilyl group at a molecular terminal, and a cyclic polysiloxanes containing a hydrosilyl group (hereinafter, sometimes referred to simply as “cyclic polysiloxane”). The cyclic polysiloxane may have a polycyclic structure, and the polycyclic structure may be a polyhedral structure. For forming the first layer 14 having high heat resistance and mechanical strength, it is preferable that a cyclic polysiloxane compound having at least two SiH groups in one molecule is used as the compound (α). The compound (α) is preferably a cyclic polysiloxane having three or more SiH groups in one molecule. From the viewpoint of heat resistance and light resistance, the group present on the Si atom is preferably a hydrogen atom or a methyl group.

Examples of the hydrosilyl group-containing polysiloxane having a linear structure include a copolymers of a dimethylsiloxane unit with a methylhydrogensiloxane unit and a terminal trimethylsiloxy unit, copolymers of a diphenylsiloxane unit with a methylhydrogensiloxane unit and a terminal trimethylsiloxy unit, copolymers of a methylphenylsiloxane unit with a methylhydrogensiloxane unit and a terminal trimethylsiloxy unit, and polysiloxanes terminally blocked with a dimethylhydrogensilyl group.

Examples of the polysiloxane having a hydrosilyl group at a molecular terminal include polysiloxanes terminally blocked with a dimethylhydrogensilyl group, and polysiloxanes including a dimethylhydrogensiloxane unit (H(CH₃)₂SiO_{1/2} unit) and one or more siloxane units selected from the group consisting of a SiO₂ unit, a SiO₃/2 unit and a SiO unit.

The cyclic polysiloxane is represented by, for example, the following general formula I.

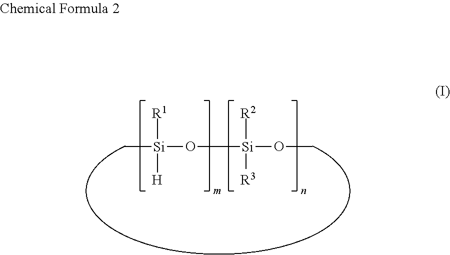

In the general formula I, R¹, R², and R³ each independently represent a monovalent organic group having 1 or more and 20 or less carbon atoms, m represents an integer of 2 or more and 10 or less, and n represents an integer of 0 or more and 10 or less. For easily carrying out the hydrosilylation reaction, m is preferably 3 or more. For easily carrying out the hydrosilylation reaction, m+n is preferably 3 or more and 12 or less. For easily carrying out the hydrosilylation reaction, n is preferably 0.

R¹, R², and R³ are each preferably an organic group having one or more elements selected from the group consisting of C, H, and O. Examples of R¹, R² and R³ include alkyl groups, hydroxyalkyl groups, alkoxyalkyl groups, oxyalkyl groups, and aryl groups. Among them, chain alkyl groups such as a methyl group, an ethyl group, a propyl group, a hexyl group, an octyl group, a decyl group and a dodecyl group; cyclic alkyl groups such as cyclohexyl groups and norbornyl groups; or a phenyl group is preferable. From the viewpoint of availability of the cyclic polysiloxane, R¹, R², and R³ are each preferably a chain alkyl group having 1 or more and 6 or less carbon atoms, or a phenyl group. For easily carrying out the hydrosilylation reaction, R¹, R², and R³ are each preferably a chain alkyl group, more preferably a chain alkyl group having 1 or more and 6 or less carbon atoms, still more preferably a methyl group.

Examples of the cyclic polysiloxane represented by the general formula I include 1,3,5,7-tetrahydrogen-1,3,5,7-tetramethylcyclotetrasiloxane, 1-propyl-3,5,7-trihydrogen-1,3,5,7-tetramethylcyclotetrasiloxane, 1,5-dihydrogen-3,7-dihexyl-1,3,5,7-tetramethylcyclotetrasiloxane, 1,3,5-trihydrogen-1,3,5-trimethylcyclotrisiloxane, 1,3,5,7,9-pentahydrogen-1,3,5,7,9-pentamethylcyclopentasiloxane, and 1,3,5,7,9,11-hexahydrogen-1,3,5,7,9,11-hexamethylcyclohexasiloxane. Among them, 1,3,5,7-tetrahydrogen-1,3,5,7-tetramethylcyclotetrasiloxane (a compound of the general formula I in which m is 4, n is 0, and R¹ is a methyl group) is preferable from the viewpoint of availability, and reactivity of the SiH group.

The compound (α) is obtained by a known synthesis method. The cyclic polysiloxane represented by the general formula I can be synthesized by, for example, a method disclosed in WO 96/15194 A or the like. The cyclic polysiloxane having a polyhedral backbone can be synthesized by, for example, a method described in Japanese Patent Laid-Open Publication No. 2004-359933, Japanese Patent Laid-Open Publication No. 2004-143449, Japanese Patent Application Laid-Open Publication No. 2006-269402, or the like. As the compound (α), a commercially available polysiloxane compound may be used.

For forming the first layer 14 further excellent in heat resistance while enhancing the developability of the first developable composition, the content ratio of the structural unit derived from the compound (α) in the component (A) is preferably 10 mass % or more and 50 mass % or less, more preferably 15 mass % or more and 45 mass % or less, based on 100 mass % of the component (A).

### (Compound (β)

The compound (β) has a carbon-carbon double bond having reactivity with a SiH group (hydrosilyl group) and a polymerizable group in one molecule, and is used for introducing a polymerizable group into a polysiloxane compound. The polymerizable group in the compound (β), together with its preferred aspects, is the same as described above for the polymerizable group of the component (A).

Examples of the group containing a carbon-carbon double bond having reactivity with a SiH group (hereinafter, sometimes referred to simply as an “alkenyl group”) include a vinyl group, an allyl group, a methallyl group, an allyloxy group (—O—CH₂—CH═CH₂), a 2-allylphenyl group, a 3-allylphenyl group, a 4-allylphenyl group, a 2-(allyloxy)phenyl group, a 3-(allyloxy) phenyl group, a 4-(allyloxy)phenyl group, a 2-(allyloxy)ethyl group, a 2,2-bis(allyloxymethyl)butyl group, a 3-allyloxy-2,2-bis (allyloxymethyl)propyl group, and a vinyl ether group. From the viewpoint of reactivity with a SiH group, the compound (β) has preferably one or more selected from the group consisting of a vinyl group, an allyl group and an allyloxy group, more preferably one or more selected from the group consisting of a vinyl group and an allyl group, as the alkenyl group.

Specific examples of the compound (β) for introducing a cationically polymerizable group include 1-vinyl-3,4-epoxycyclohexane, allyl glycidyl ether, allyl oxetanyl ether, diallyl monoglycidyl isocyanurate, and monoallyl diglycidyl isocyanurate. From the viewpoint of reactivity in cationic polymerization, the compound (β) is preferably a compound having one or more functional groups selected from the group consisting of an alicyclic epoxy group and a glycidyl group, more preferably a compound having an alicyclic epoxy group. For further enhancing the reactivity in cationic polymerization, the compound (β) is preferably one or more compounds selected from the group consisting of allyl glycidyl ether and 1-vinyl-3,4-epoxycyclohexane, more preferably 1-vinyl-3,4-epoxycyclohexane.

Specific examples of the compound (β) for introducing a radically polymerizable group include vinyl acrylate, vinyl methacrylate, allyl acrylate, allyl methacrylate, 2-butenyl acrylate, and 2-butenyl methacrylate. From the viewpoint of reactivity in radical polymerization, the compound (β) is preferably one or more selected from the group consisting of a vinyl acrylate and an allyl acrylate, more preferably an allyl acrylate.

For forming the first layer 14 further excellent in heat resistance while enhancing the developability of the first developable composition, the content ratio of the structural unit derived from the compound (β) in the component (A) is preferably 20 mass % or more and 50 mass % or less, more preferably 22 mass % or more and 45 mass % or less, based on 100 mass % of the component (A).

### (Compound (γ))

The compound (γ) has a carbon-carbon double bond having reactivity with a SiH group and an alkali-soluble group in one molecule, and is used for introducing an alkali-soluble group into a polysiloxane compound. The alkali-soluble group in the compound (γ), together with its preferred aspects, is the same as described above for the alkali-soluble group of the component (A).

The compound (γ) has a group containing a carbon-carbon double bond having reactivity with a SiH group (alkenyl group). Examples of the alkenyl group of the compound (γ), together with its preferred aspects, include those exemplified above for the alkenyl group of the compound (β). That is, the compound (γ) has preferably one or more selected from the group consisting of a vinyl group, an allyl group and an allyloxy group, more preferably one or more selected from the group consisting of a vinyl group and an allyl group, as the alkenyl group.

The compound (γ) may have two or more alkenyl groups in one molecule. When the compound (γ) contains a plurality of alkenyl groups in one molecule, a plurality of compounds (a) can be crosslinked by the hydrosilylation reaction, and therefore the crosslinking density of the resulting cured product tends to increase, resulting in improvement of the heat resistance of the cured product.

Specific examples of the compound (γ) include diallyl isocyanurate, monoallyl isocyanurate, 2,2′-diallyl bisphenol A, vinylphenol, allylphenol, butenoic acid, pentenoic acid, hexenoic acid, heptenoic acid, and undecylenic acid.

For obtaining a first developable composition which is excellent in developability, the compound (γ) is preferably one or more selected from the group consisting of diallyl isocyanurate, monoallyl isocyanurate and 2,2′-diallyl bisphenol A, more preferably one or more selected from the group consisting of diallyl isocyanurate and monoallyl isocyanurate. When monoallyl isocyanurate is used as the compound (γ), a component (A) having the X1 group as an alkali-soluble group is obtained. When diallyl isocyanurate is used as the compound (γ), a component (A) having the X2 group as an alkali-soluble group is obtained.

For obtaining a first developable composition further excellent in developability, the content ratio of the structural unit derived from the compound (γ) in the component (A) is preferably 5 mass % or more and 50 mass % or less, more preferably 10 mass % or more and 30 mass % or less, based on 100 mass % of the component (A).

### (Other Starting Substances)

In addition to the compound (α), compound (β) and compound (γ), other starting substances may be used in the hydrosilylation reaction. For example, an alkenyl group-containing compound which is different from the compound (β) and compound (γ) (hereinafter, sometimes referred to as “another alkenyl group-containing compound”) may be used as the other starting substance.

For obtaining the first layer 14 further excellent in heat resistance, it is preferable to use a compound having two or more alkenyl groups in one molecule (hereinafter, sometimes referred to as a “compound (δ)”) as another alkenyl group-containing compound. When the compound (δ) is used, the heat resistance of the resulting first layer 14 tends to be further improved because the number of crosslinking points increases during the hydrosilylation reaction.

Specific examples of the compound (δ) include diallyl phthalate, triallyl trimellitate, diethylene glycol bisallyl carbonate, 1,1,2,2-tetraallyloxyethane, triallyl cyanurate, triallyl isocyanurate, diallyl monobenzyl isocyanurate, diallyl monomethyl isocyanurate, 1,2,4-trivinylcyclohexane, triethylene glycol divinyl ether, divinylbenzene, divinylbiphenyl, 1,3-diisopropenylbenzene, 1,4-diisopropenylbenzene, 1,3-bis(allyloxy)adamantane, 1,3-bis(vinyloxy)adamantane, 1,3,5-tris(allyloxy)adamantane, 1,3,5-tris(vinyloxy)adamantane, dicyclopentadiene, vinylcyclohexene, 1,5-hexadiene, 1,9-decadiene, diallyl ether, and oligomers thereof.

For further improving the heat resistance of the resulting first layer 14, the compound (δ) is preferably one or more selected from the group consisting of triallyl isocyanurate and diallyl monomethyl isocyanurate, more preferably diallyl monomethyl isocyanurate.

For enhancing alkali developability while further improving the heat resistance of the resulting first layer 14, the content ratio of the structural unit derived from the compound (δ) in the component (A) is preferably 5 mass % or more and 30 mass % or less, more preferably 8 mass % or more and 20 mass % or less, based on 100 mass % of the component (A).

### (Hydrosilylation Reaction)

The order and the method of the hydrosilylation reaction for obtaining the component (A) are not particularly limited. For example, the component (A) is obtained by a hydrosilylation reaction conforming to a method disclosed in WO 2009/075233 and using the compound (α), the compound (β), the compound (γ), and other starting substances as optional components if necessary. The component (A) obtained using the compound (α), the compound (β), the compound (γ), and other starting substances as optional components if necessary is, for example, a polymer having a plurality of polymerizable groups and a plurality of alkali-soluble groups in one molecule, and a polysiloxane structure in the main chain.

The proportion of each compound in the hydrosilylation reaction is not particularly limited, but the total amount A of alkenyl groups and the total amount B of SiH groups in the starting substance preferably satisfy 1≤B/A≤30, and more preferably satisfy 1≤B/A≤10.

In the hydrosilylation reaction, a hydrosilylation catalyst such as chloroplatinic acid, a platinum-olefin complex, or a platinum-vinylsiloxane complex may be used. The hydrosilylation catalyst and a co-catalyst may be used in combination. The addition amount (substance amount) of the hydrosilylation catalyst is not particularly limited, and is preferably 10⁻⁸ or more and 10⁻¹ or less times, more preferably 10⁻⁶ or more and 10⁻² or less times the total substance amount of alkenyl groups contained in the starting substance.

The temperature of the hydrosilylation reaction may be appropriately set, and is preferably 30° C. or higher and 200° C. or lower, more preferably 50° C. or higher and 150° C. or lower. The oxygen concentration of the gas phase portion in the hydrosilylation reaction is preferably 3 vol % or less. From the viewpoint of accelerating the hydrosilylation reaction, the gas phase portion may contain oxygen in an amount of 0.1 vol % or more and 3 vol % or less.

A solvent may be used in the hydrosilylation reaction. As the solvent, a single solvent or a mixture of two or more solvents can be used. Examples of the solvent that can be used include hydrocarbon-based solvents such as benzene, toluene, xylene, hexane, and heptane; ether-based solvents such as tetrahydrofuran, 1,4-dioxane, 1,3-dioxolane, and diethyl ether; ketone-based solvents such as acetone and methyl ethyl ketone; halogen-based solvents such as chloroform, methylene chloride, and 1,2-dichloroethane. Toluene, xylene, tetrahydrofuran, 1,4-dioxane, 1,3-dioxolane, or chloroform is preferable because it is easily distilled off after the reaction. In the hydrosilylation reaction, a gelling inhibitor may be used if necessary.

For obtaining the substrate laminate L1 further excellent in adhesiveness between substrates, the content ratio of the first curable compound in the first developable composition is preferably 20 mass % or more and 99 mass % or less based on the total solid content of the first developable composition.

Next, the first photopolymerization initiator will be described. The first photopolymerization initiator can be appropriately selected according to the polymerizable group of the first curable compound. That is, when the first curable compound is cationically polymerizable, a photocationic polymerization initiator is used as the first photopolymerization initiator, and when the first curable compound is radically polymerizable, a photoradical polymerization initiator is used as the first photopolymerization initiator.

Examples of the photocationic polymerization initiator include photocationic polymerization initiators having one or more structures selected from the group consisting of a naphthalimide structure and an oxime sulfonate structure, carboxylic acid ester-based compounds, and onium salt-based compounds. From the viewpoint of ease of patterning, the photocationic polymerization initiator is preferably a photocationic polymerization initiator having one or more structures selected from the group consisting of a naphthalimide structure and an oxime sulfonate structure, more preferably a photocationic polymerization initiator having a naphthalimide structure.

From the viewpoint of photosensitivity, the naphthalimide structure is preferably a structure represented by the following general formula II. From the viewpoint of photosensitivity, the photocationic polymerization initiator having a naphthalimide structure is preferably a compound represented by the following general formula II.

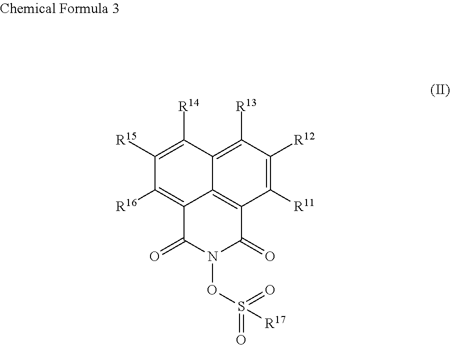

In the general formula II, R¹¹ to R¹⁶ each independently represent a hydrogen atom; an alkyl group having 1 or more and 14 or less carbon atoms and optionally substituted with a halogen atom; a cycloalkyl group having 3 or more and 12 or less carbon atoms and optionally substituted with a halogen atom; or an alkoxy group having 4 or more and 18 or less carbon atoms and optionally substituted with a halogen atom or a heterocyclic group having 3 or more and 20 or less carbon atoms; and R¹⁷ represents an alkyl group having 1 or more and 18 or less carbon atoms and optionally substituted with a halogen atom; an aryl group having 6 or more and 20 or less carbon atoms and optionally substituted with a halogen atom, an alkyl group having 1 or more and 14 or less carbon atoms, a cycloalkyl group having 3 or more and 12 or less carbon atoms, or an acyl group having 2 or more and 4 or less carbon atoms; or a cycloalkyl group having 3 or more and 12 or less carbon atoms and optionally substituted with a halogen atom, an alkyl group having 1 or more and 4 or less carbon atoms, or a halogenated alkyl group having 1 or more and 4 or less carbon atoms.

For increasing the acid generation rate during irradiation with an active energy ray while increasing the solubility in a solvent, the number of carbon atoms in each of the substituents represented by R¹¹ to R¹⁶ is preferably 1 or more and 14 or less, more preferably 3 or more and 8 or less.

Specific examples of the photocationic polymerization initiator having a naphthalimide structure represented by the general formula II include, but are not limited to, SP-082, SP-606, SP-601, SP-613 and SP-103 manufactured by ADEKA Corporation.

From the viewpoint of photosensitivity, the oxime sulfonate structure is preferably a structure represented by the following general formula III. From the viewpoint of photosensitivity, the photocationic polymerization initiator having an oxime sulfonate structure is preferably a compound represented by the following general formula III.

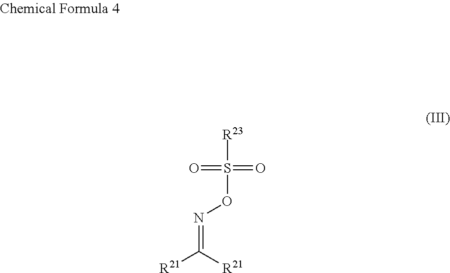

In the general formula III, R²¹ and R²² each independently represent a hydrogen atom; a cyano group; an aryl group having 6 or more and 30 or less carbon atoms and optionally substituted with a halogen atom, an alkyl group having 1 or more and 4 or less carbon atoms, an alkoxy group having 1 or more and 4 or less carbon atoms, or a halogenated alkyl group having 1 or more and 4 or less carbon atoms; an alkyl group having 1 or more and 14 or less carbon atoms and optionally substituted with a halogen atom; a cycloalkyl group having 3 or more and 12 or less carbon atoms; an alkoxy group having 4 or more and 18 or less carbon atoms and optionally substituted with a halogen atom or a heterocyclic group having 3 or more and 20 or less carbon atoms; or an alkylthio group having 4 or more and 18 or less carbon atoms and optionally substituted with a halogen atom, a cycloalkyl group having 3 or more and 12 or less carbon atoms or a heterocyclic group having 3 or more and 20 or less carbon atoms, R²¹ and R²² may be bonded to each other to form a heterocyclic ring having 2 or more and 8 or less carbon atoms, and R²³ is an alkyl group having 1 or more and 20 or less carbon atoms and optionally substituted with a halogen atom; an alkenyl group having 2 or more and 20 or less carbon atoms; an alkynyl group having 2 or more and 20 or less carbon atoms; a halogen atom; a cycloalkyl group having 3 or more and 20 or less carbon atoms and optionally substituted with a halogen atom, an alkyl group having 1 or more and 4 or less carbon atoms or a halogenated alkyl group having 1 or more and 4 or less carbon atoms; a cycloalkenyl group having 3 or more and 20 or less carbon atoms and optionally substituted with a halogen atom, an alkyl group having 1 or more and 4 or less carbon atoms or a halogenated alkyl group having 1 or more and 4 or less carbon atoms; a heterocyclic group having 3 or more and 20 or less carbon atoms and optionally substituted with a halogen atom, an alkyl group having 1 or more and 4 or less carbon atoms or a halogenated alkyl group having 1 or more and 4 or less carbon atoms; or an aryl group having 6 or more and 20 or less carbon atoms and optionally substituted with a halogen atom, an alkyl group having 1 or more and 14 or less carbon atoms or a halogenated alkyl group having 1 or more and 14 or less carbon atoms.

When one of R²¹ and R²² in the general formula III is a substituted aryl group, the photocationic polymerization initiator having a structure represented by the general formula III may have two partial structures other than the “substituted aryl group” in the general formula III. In this case, the photocationic polymerization initiator has a structure in which the two partial structures are linked by a divalent organic group containing an aromatic ring.

Specific examples of the photocationic polymerization initiator having an oxime sulfonate structure represented by the general formula III include, but are not limited to, Irgacure (registered trademark) PAG 103, Irgacure (registered trademark) PAG 121, Irgacure (registered trademark) PAG 203, CGI 725 and CGI 1907 each manufactured by BASF SE.

Examples of the onium salt-based compound include sulfonium salt-based compounds and iodonium salt-based compounds.

The photocationic polymerization initiators listed in descending order in terms of acid strength of the acid generated are as follows: compounds containing SbF₆⁻ as an anion, compounds containing B(C₆F₅)₄⁻ as an anion, compounds containing PF₆⁻ as an anion, compounds containing CF₃SO₃⁻ as an anion, and compounds containing HSO₄⁻ as an anion. When a photocationic polymerization initiator which generates an acid having high acid strength is used, the residual film ratio tends to increase. The pKa of the acid generated from the photocationic polymerization initiator is preferably less than 3, more preferably less than 1.

Examples of the cation of the sulfonium salt-based compound include cations represented by the following chemical formula IV

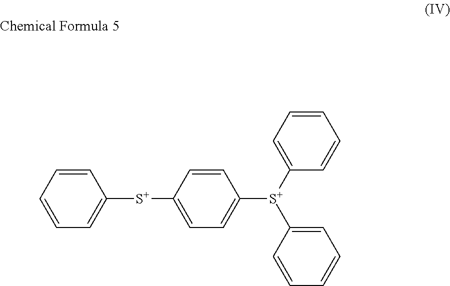

Examples of the commercially available product of the sulfonium salt-based compound (sulfonium salt-based photocationic polymerization initiator) include a photocationic polymerization initiator containing a fluoroalkyl fluorophosphate (anion) and a cation represented by chemical formula IV (“CPI-210S” manufactured by San-Apro Ltd).

Specific examples of the photoradical polymerization initiator include acetophenone-based compounds, acylphosphine oxide-based compounds, benzoin-based compounds, benzophenone-based compounds, α-diketone-based compounds, biimidazole-based compounds, polynuclear quinone-based compounds, triazine-based compounds, oxime ester-based compounds, titanocene-based compounds, xanthone-based compounds, thioxanthone-based compounds, ketal-based compounds, azo-based compounds, peroxides, 2,3-dialkyldione-based compounds, disulfide-based compounds, and fluoroamine-based compounds. For suppressing film loss during development, the photoradical polymerization initiator is preferably one or more selected from the group consisting of an acetophenone-based compound, a benzophenone-based compound and an oxime ester-based compound, more preferably an oxime ester-based compound.

Examples of the oxime ester-based compound include 1,2-octanedione 1-[4-(phenylthio)-2-(O-benzoyloxime)], and ethanone 1-[9-ethyl-6-(2-methylbenzoyl)-9H-carbazole-3-yl]-1-(O-acetyloxime).

The content of the first photopolymerization initiator in the first developable composition is not particularly limited. From the viewpoint of the balance between the curing rate and the physical properties of the cured product, the content of the first photopolymerization initiator is preferably 0.1 parts by mass or more and 20 parts by mass or less, more preferably 0.5 parts by mass or more and 10 parts by mass or less, based on 100 parts by mass of the first curable compound.

Next, other components that may be contained in the first developable composition (components other than the first curable compound and the first photopolymerization initiator) will be described.

### (Solvent)

The first developable composition may contain a solvent. For example, the first curable compound and first photopolymerization initiator, and other components used if necessary as described later are dissolved or dispersed in a solvent to obtain a first developable composition.

Specific examples of the solvent include hydrocarbon-based solvents such as benzene, toluene, hexane, and heptane; ether-based solvents such as tetrahydrofuran, 1,4-dioxane, 1,3-dioxolane, and diethyl ether; ketone-based solvents such as acetone, methyl ethyl ketone, methyl isobutyl ketone, and cyclohexanone; glycol-based solvents such as propylene glycol 1-monomethyl ether 2-acetate, diethylene glycol dimethyl ether, diethylene glycol ethyl methyl ether, and ethylene glycol diethyl ether; ester-based solvents such as isobutyl isobutyrate; and halogen-based solvents such as chloroform, methylene chloride, and 1,2-dichloroethane. From the viewpoint of the applicability (film formation stability) of the first developable composition, the solvent is preferably a glycol-based solvent, more preferably propylene glycol 1-monomethyl ether 2-acetate.

From the viewpoint of applicability (film formation stability) of the first developable composition, the amount of the solvent is preferably 10 parts by mass or more and 100 parts by mass or less, more preferably 20 parts by mass or more and 80 parts by mass or less, based on 100 parts by mass of the first curable compound.

### (Sensitizer)

The first developable composition may contain a sensitizer. By using a sensitizer, the patterning property is improved. The sensitizer is preferably an anthracene-based compound. Specific examples of the anthracene-based compound include anthracene, 2-ethyl-9,10 dimethoxyanthracene, 9,10-dimethylanthracene, 9,10-dibutoxyanthracene, 9,10-dipropoxyanthracene, 9,10-diethoxyanthracene, 1,4-dimethoxyanthracene, 9-methylanthracene, 2-ethylanthracene, 2-t-butylanthracene, 2,6-di-t-butylanthracene, and 9, 10 diphenyl-2,6-di-t-butylanthracene. Among them, 9,10-dibutoxyanthracene, 9,10-dipropoxyanthracene, and 9,10-diethoxyanthracene are preferable from the viewpoint of compatibility with the first developable composition.

The content of the sensitizer in the first developable composition is not particularly limited, and is preferably 0.01 parts by mass or more and 20 parts by mass or less, more preferably 0.1 parts by mass or more and 15 parts by mass or less, based on 100 parts by mass of the first curable compound, from the viewpoint of curability and the balance of the physical properties of the cured product.

### [Second Developable Composition]

Next, the second developable composition as a material for the second layer 15 will be described. The second developable composition contains a polymerizable second curable compound, a second photopolymerization initiator, and a colorant. As the second curable compound, any of the curable compounds shown as examples of the first curable compound can be used. As the second photopolymerization initiator, any of the photopolymerization initiators shown as examples of the first photopolymerization initiator can be used. The second curable compound and the second photopolymerization initiator of the second developable composition may be the same as or different from the first curable compound and the first photopolymerization initiator of the first developable composition, respectively. The content ratio of the second curable compound and the content ratio of the second photopolymerization initiator in the second developable composition may be the same as or different from the content ratio of the first curable compound and the content ratio of the first photopolymerization initiator in the first developable composition, respectively.

### (Colorant)

The second developable composition contains a colorant. Since the second developable composition contains a colorant, the colored second layer 15 is obtained. Examples of the colorant include organic pigments, inorganic pigments, and dyes. From the viewpoint of heat resistance and colorability, the colorant is preferably a pigment. When a black colored pattern such as a black partition wall (black rib member) having a light shielding property is formed, it is preferable to use a black pigment as the colorant, but the colorant is not limited to a black pigment. As a colored pattern other than a black pattern, a colored pattern such as a red pattern, a yellow pattern or a blue pattern is used according to a use purpose.

Examples of the black pigment that generally absorbs light in a visible wavelength range include anthraquinone-based black pigments, perylene-based black pigments (perylene black), azo-based black pigments, and lactam-based black pigments (lactam black). A mixed-color organic pigment may be used in which two or more chromatic pigments are blended so that the resulting mixture is black, that is, light in a visible wavelength range is generally absorbed. For efficiently reducing the light transmittance, the mixed-color organic pigment is preferably a pigment containing one or more selected from the group consisting of a blue pigment and a purple pigment.

Examples of the inorganic pigment include composite metal oxide pigments, carbon black, black titanium sub-oxynitride, titanium oxide (more specifically, titanium black and the like), lead sulfate, lead yellow, red iron oxide, ultramarine blue, iron blue, chromium oxide, antimony white, zinc sulfide, zinc, manganese purple, cobalt purple, barium sulfate, and magnesium carbonate. Examples of the dye include azo-based compounds, anthraquinone-based compounds, perylene-based compounds, perinone-based compounds, phthalocyanine-based compounds, carbonium-based compounds, and indigoid-based compounds.

As pigments for obtaining a colored pattern other than a black pattern, chromatic pigments such as red, orange, yellow, green, blue, purple, cyanine, and magenta pigments may be used.

For further enhancing the heat resistance of second layer 15, the colorant to be used is preferably an inorganic pigment, more preferably carbon black. The inorganic pigment is excellent in heat resistance, and is hardly decomposed by heating. For obtaining the second layer 15 further excellent in heat resistance, the proportion of the inorganic pigment in the colorant is preferably 60 mass % or more, more preferably 70 mass % or more, still more preferably 75 mass % or more.

For obtaining a second developable composition capable of forming the second layer 15 which is highly developable and further excellent in light shielding property and heat resistance, the amount of the colorant is preferably 0.005 mass % or more and 80 mass % or less, more preferably 0.01 mass % or more and 80 mass % or less, still more preferably 0.1 mass % or more and 50 mass % or less, still more preferably 0.1 mass % or more and 10 mass % or less based on the total solid content of the second developable composition. When the amount of the colorant is 0.1 mass % or more and 10 mass % or less based on the total solid content of the second developable composition, it is possible to enhance the light shielding property and the adhesive strength between substrates while further suppressing deposition of foreign matter derived from the colorant.

Except for the above (except for the points described above), the second developable composition is as described in the section [First developable composition] above.

### [Other Examples of Configuration of Substrate Laminate L1]

Next, other examples of the configuration of the substrate laminate L1 will be described with reference to FIGS. 2 to 6. FIGS. 2 to 6 are sectional views each showing another example of the configuration of the substrate laminate L1.

In a substrate laminate 20 shown in FIG. 2, the second layer 15 is directly bonded to the second substrate 12. That is, the substrate laminate 20 does not include the adhesive layer 16 (see FIG. 1). Except for the above, the substrate laminate 20 is the same as the substrate laminate 10. The substrate laminate 20 enables simplification of the manufacturing process because the step of providing the adhesive layer 16 is not necessary.

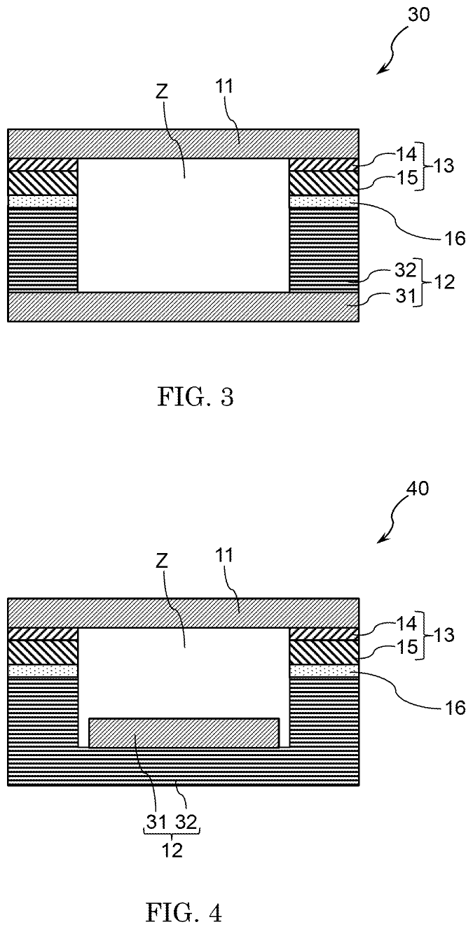

In a substrate laminate 30 shown in FIG. 3, the second substrate 12 includes a semiconductor element substrate 31 and a frame member 32. The frame member 32 and the first substrate 11 are bonded to each other with the cured product layer 13 and the adhesive layer 16 interposed therebetween. That is, in the substrate laminate 30, the first substrate 11, the cured product layer 13, the adhesive layer 16, the frame member 32, and the semiconductor element substrate 31 are laminated in this order. As a material for the frame member 32, an epoxy resin, ceramic, or the like may be used. The thickness (height) of the frame member 32 is, for example, 30 μm or more and 30,000 μm or less. When the frame member 32 is used, the hollow portion Z widens, so that, for example, an interposer or the like (not shown) can be easily disposed in the hollow portion Z. The frame member 32 may be bonded to the semiconductor element substrate 31 in advance with an adhesive, or may be formed on the semiconductor element substrate 31 by molding or the like. Except for the above, the substrate laminate 30 is the same as the substrate laminate 10.

In a substrate laminate 40 shown in FIG. 4, the frame member 32 is a concave structure. The semiconductor element substrate 31 and the frame member 32 are integrated with each other with the semiconductor element substrate 31 being in contact with the inside of the concave portion of the frame member 32. Except for the above, the substrate laminate 40 is the same as the substrate laminate 30.

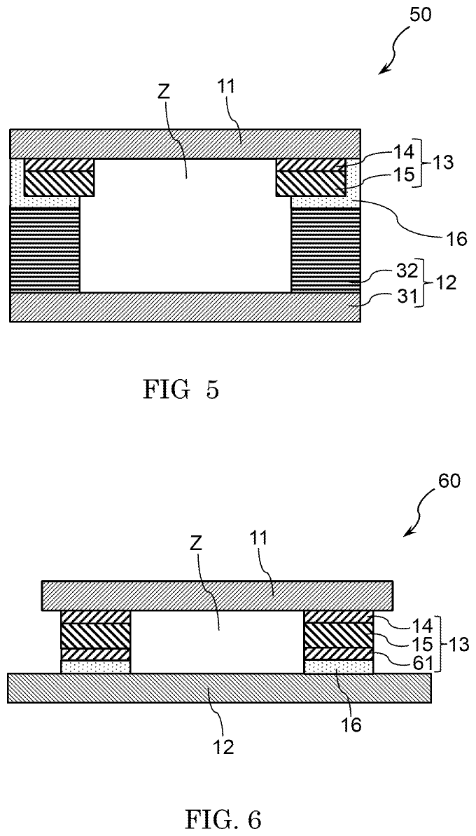

In a substrate laminate 50 shown in FIG. 5, a part of the adhesive layer 16 is disposed between the first substrate 11 and the frame member 32. Except for the above, the substrate laminate 50 is the same as the substrate laminate 30.

In a substrate laminate 60 shown in FIG. 6, the cured product layer 13 includes the first layer 14, the second layer 15, and a third layer 61 including a cured product of a third developable composition in this order from the first substrate 11 side. In the substrate laminate 60, the third layer 61 and the second substrate 12 are bonded to each other with the adhesive layer 16 interposed therebetween. The thickness (height) of the third layer 61 is, for example, 0.01 μm or more and 100 μm or less. The third developable composition contains a polymerizable third curable compound and a third photopolymerization initiator and is free of a colorant. The phrase “the third developable composition is free of a colorant” means that the amount of the colorant in the third layer 61 including a cured product of the third developable composition is less than 0.1 parts by mass (preferably less than 0.01 parts by mass, more preferably less than 0.001 parts by mass, still more preferably less than 0.0001 parts by mass) based on 100 parts by mass of the colorant in the second layer 15 including a cured product of the second developable composition.

As the third curable compound, any of the curable compounds shown as examples of the first curable compound can be used. As the third photopolymerization initiator, any of the photopolymerization initiators shown as examples of the first photopolymerization initiator can be used. The third curable compound and the third photopolymerization initiator of the third developable composition may be the same as or different from the first curable compound and the first photopolymerization initiator of the first developable composition, respectively. The content ratio of the third curable compound and the content ratio of the third photopolymerization initiator in the third developable composition may be the same as or different from the content ratio of the first curable compound and the content ratio of the first photopolymerization initiator in the first developable composition, respectively. Except for the above (except for the points described above), the third developable composition is as described in the section [First developable composition] above.

Since the third developable composition as a constituent material for the third layer 61 does not contain a colorant, the patterning property in formation of the third layer 61 is better than the patterning property in formation of the second layer 15. Therefore, the thickness of the third layer 61 can be relatively easily increased. Thus, in the substrate laminate 60, the thickness of the cured product layer 13 can be relatively easily increased because the cured product layer 13 includes the third layer 61. When the cured product layer 13 has a large thickness, for example, a sealing resin layer (not shown) can be easily formed on the periphery of the cured product layer 13.

Except for the above, the substrate laminate 60 is the same as the substrate laminate 10.

### Second Embodiment: Substrate Laminate

Next, a substrate laminate according to a second embodiment of the present invention will be described. A substrate laminate according to the second embodiment of the present invention (hereinafter, sometimes referred to as a “substrate laminate L2”) includes a first substrate, a second substrate, an adhesive layer bonding the first substrate and the second substrate, and a cured product layer disposed on a surface of the first substrate on a side opposite to the second substrate side. The cured product layer is patterned, and includes a first layer including a cured product of a first developable composition, and a second layer including a cured product of a second developable composition, in this order from the first substrate side. The first developable composition which contains a polymerizable first curable compound and a first photopolymerization initiator and is free of a colorant. The second developable composition contains a polymerizable second curable compound, a second photopolymerization initiator, and a colorant. The details of the first developable composition and the second developable composition in the second embodiment are the same as the details of the first developable composition and the second developable composition in the first embodiment, respectively, and the descriptions thereof are omitted. The details of the first substrate, the second substrate, the adhesive layer, the cured product layer, the first layer and the second layer of the substrate laminate L2 are the same as the details of the first substrate, the second substrate, the adhesive layer, the cured product layer, the first layer and the second layer of the substrate laminate L1, respectively, and the descriptions thereof are omitted.

The substrate laminate L2 can be manufactured by a manufacturing method according to a fourth embodiment described later. Thus, in manufacturing the substrate laminate L2, a first film formed of the first developable composition free of a colorant can be formed on the first substrate, followed by formation of a second film formed of the second developable composition containing a colorant on the first film. This enables suppression of contact between the second developable composition containing a colorant and the first substrate. Further, in a step Sc in a manufacture method according to the fourth embodiment described later, a second non-exposed layer formed of the second developable composition containing a colorant can be removed, followed by removal of a first non-exposed layer composed of the first developable composition free of a colorant, so that it is possible to suppress the remaining of the colorant between patterns during development. Therefore, the substrate laminate L2 is resistant to deposition of foreign matter derived from a colorant.

### [Configuration of Substrate Laminate L2]

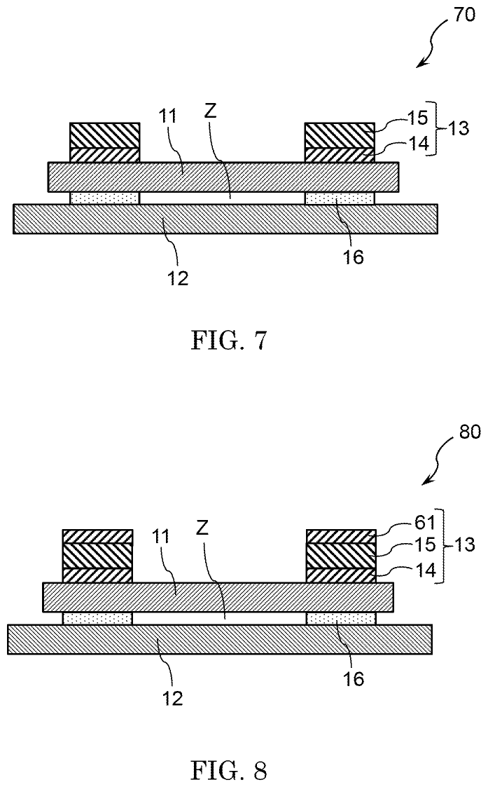

Hereinafter, an example of a configuration of the substrate laminate L2 will be described with reference to the drawings as appropriate. FIG. 7 is a sectional view showing an example of the substrate laminate L2. A substrate laminate 70 shown in FIG. 7 includes a first substrate 11, a second substrate 12, the adhesive layer 16 bonding the first substrate 11 and the second substrate 12, and the cured product layer 13 disposed on a surface of the first substrate 11 on a side opposite to the second substrate 12 side. The cured product layer 13 is patterned, and includes the first layer 14 and the second layer 15 in this order from the first substrate 11 side. When the substrate laminate 70 is applied to an image sensor, the adhesive layer 16 is provided so as to surround a light receiving element (not shown) provided on the second substrate 12.

In the substrate laminate 70, the second layer 15 includes a cured product of the second developable composition containing a colorant. Thus, the second layer 15 can be used as, for example, a light-shielding film for suppressing flare and ghost. When the substrate laminate 70 is applied to an image sensor, for example, the cured product layer 13 is provided so as to surround a light receiving element (not shown) provided on the second substrate 12 in plan view of the substrate laminate 70 from the first substrate 11 (for example, a glass substrate).

### [Another Example of Configuration of Substrate Laminate L2]

Next, another example of the configuration of the substrate laminate L2 will be described with reference to FIG. 8. In a substrate laminate 80 shown in FIG. 8, the cured product layer 13 includes the first layer 14, the second layer 15 and the third layer 61 including a cured product of the third developable composition in this order from the first substrate 11 side. The thickness (height) of the third layer 61 is, for example, 0.01 μm or more and 100 μm or less. The third developable composition contains a polymerizable third curable compound and a third photopolymerization initiator and is free of a colorant. The phrase “the third developable composition is free of a colorant” means that the amount of the colorant in the third layer 61 including a cured product of the third developable composition is less than 0.1 parts by mass (preferably less than 0.01 parts by mass, more preferably less than 0.001 parts by mass, still more preferably less than 0.0001 parts by mass) based on 100 parts by mass of the colorant in the second layer 15 including a cured product of the second developable composition.

As the third curable compound, any of the curable compounds shown as examples of the first curable compound in the first embodiment can be used. As the third photopolymerization initiator, any of the photopolymerization initiators shown as examples of the first photopolymerization initiator in the first embodiment can be used. The third curable compound and the third photopolymerization initiator of the third developable composition may be the same as or different from the first curable compound and the first photopolymerization initiator of the first developable composition as a constituent material for the first layer 14, respectively. The content ratio of the third curable compound and the content ratio of the third photopolymerization initiator in the third developable composition may be the same as or different from the content ratio of the first curable compound and the content ratio of the first photopolymerization initiator in the first developable composition as a constituent material for the first layer 14, respectively. Except for the above (except for the points described above), the third developable composition is as described in the section [First developable composition] in the first embodiment above.

Since the third developable composition as a constituent material for the third layer 61 does not contain a colorant, the patterning property in formation of the third layer 61 is better than the patterning property in formation of the second layer 15. Therefore, the thickness of the third layer 61 can be relatively easily increased. Thus, in the substrate laminate 80, the thickness of the cured product layer 13 can be relatively easily increased because the cured product layer 13 includes the third layer 61. When the cured product layer 13 has a large thickness, for example, a sealing resin layer (not shown) can be easily formed on the periphery of the cured product layer 13. Except for the above, the substrate laminate 80 is the same as the substrate laminate 70.

Except for the above (except for the points described above), the substrate laminate L2 is as described in the section <First embodiment: substrate laminate> above.

### <Uses of Substrate Laminate L1 and Substrate Laminate L2>

The substrate laminate L1 and the substrate laminate L2 are each used as, for example, a member that forms micro electromechanical systems (IEMS). Preferably, the substrate laminate L1 and the substrate laminate L2 are each used as a member that forms a sensor such as an image sensor, an acceleration sensor, or a pressure sensor.

When the substrate laminate L1 or the substrate laminate L2 is applied to an image sensor, it is possible to suppress an occurrence of imaging errors such as reflection during imaging because the image sensor including the substrate laminate L1 or the substrate laminate L2 is resistant to deposition of foreign matter derived from a colorant. In an image sensor including the substrate laminate L1 or the substrate laminate L2, for example, one of the first substrate 11 and the second substrate 12 is a transparent substrate, and the other is a semiconductor element substrate (image sensor substrate).

### Third Embodiment: Method for Manufacturing Substrate Laminate

Next, a method for manufacturing a substrate laminate according to the third embodiment of the present invention (hereinafter, sometimes referred to as a “manufacturing method M1”) will be described with reference to the drawings as appropriate. The manufacturing method M1 is a suitable method for manufacturing the substrate laminate according to the first embodiment (substrate laminate L1). In the following description, descriptions of contents overlapping with those of the first embodiment may be omitted.

The manufacture method M1 includes a step Sa, a step Sb, the step Sc, and the step Sd1. In the step Sa, a coating film is formed on the first substrate. In the step Sb, the coating film is irradiated with an active energy ray through a photomask to form an exposed portion in a semi-cured state and a non-exposed portion on the first substrate. In the step Sc, the non-exposed portion is removed from the first substrate with a developer to form a patterned coating film (hereinafter, sometimes referred to as a “pattern film”) on the first substrate. In the step Sd1, the first substrate and the second substrate are bonded with the pattern film interposed therebetween. The pattern film in the step Sd1 includes two types of films: a coating film patterned in a semi-cured state and a film obtained by further curing the coating film patterned in a semi-cured state (a cured product layer including a cured product of the patterned coating film).

The exposed portion in a semi-cured state, which is formed in the step Sb, includes a first semi-cured layer formed of the first developable composition in a semi-cured state and a second semi-cured layer formed of the second developable composition in a semi-cured state, in this order from the first substrate side. The first developable composition contains a polymerizable first curable compound and a first photopolymerization initiator and is free of a colorant. The second developable composition contains a polymerizable second curable compound, a second photopolymerization initiator, and a colorant.

In the manufacturing method M1, a first film formed of the first developable composition free of a colorant can be formed on the first substrate, followed by formation of a second film formed of the second developable composition containing a colorant on the first film. This enables suppression of contact between the second developable composition containing a colorant and the first substrate. Further, in step Sc, a second non-exposed layer formed of the second developable composition containing a colorant can be removed, followed by removal of a first non-exposed layer composed of the first developable composition free of a colorant, so that it is possible to suppress the remaining of the colorant between patterns during development. For this reason, the manufacturing method M1 enables suppression of deposition of foreign matter derived from the colorant.

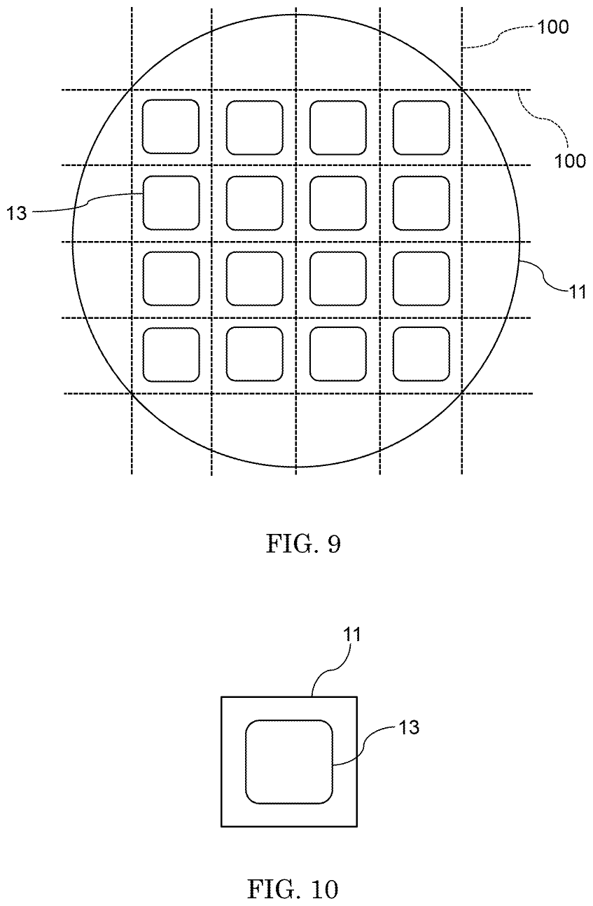

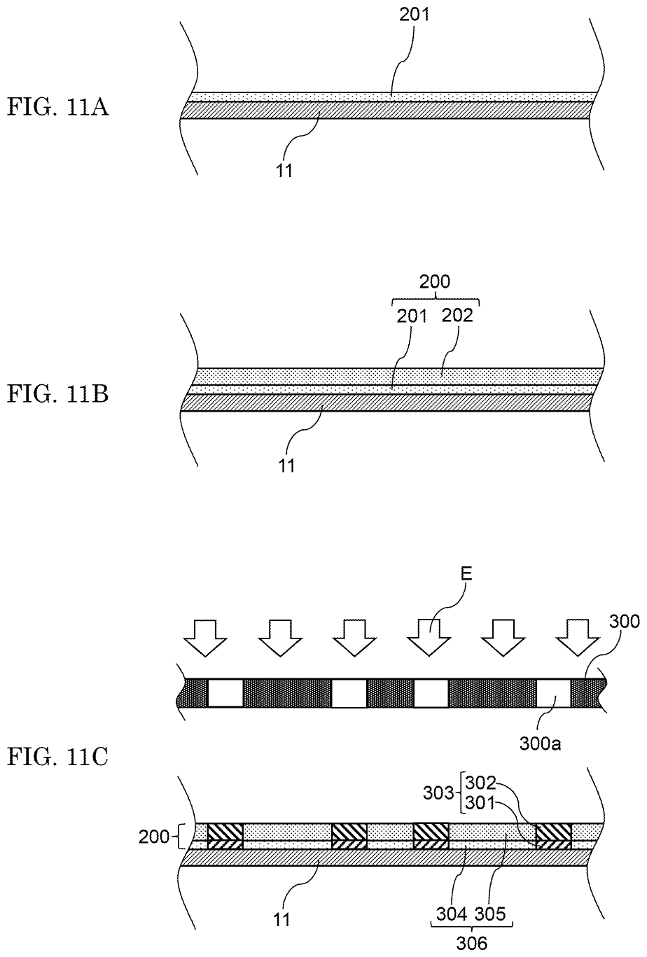

Hereinafter, each step in an example of the manufacturing method M1 will be described with reference to the drawings as appropriate. FIG. 9 referred here is a plan view showing an example of a first substrate after formation of a cured product layer in manufacture of a substrate laminate by the manufacturing method M1. FIG. 10 referred here is a plan view showing an example of a first substrate after formation and singulation of a cured product layer in manufacturing a substrate laminate by the manufacturing method M1. FIGS. 11A to 11C, 12A to 12C, and 13A to 13C are step-by-step sectional views showing an example of the manufacturing method M1.

In an example of the manufacturing method M1, first, a large number of patterned cured product layers 13 each having a quadrangle-cylindrical shape are formed on a large-sized first substrate 11 (FIG. 9). The pattern of the cured product layer 13 is not limited to the pattern shown in FIG. 9, and may be designed on the basis of an intended shape. The pattern may have a grid shape or the like. The number of patterns of the cured product layer 13 is not particularly limited as long as at least one pattern is formed. The patterned cured product layer 13 shown in FIG. 9 can be formed by the steps described in detail below.

### (Step Sa)

Hereinafter, a first method for the step Sa will be described. In the first method, a first developable composition is applied to one surface of the large-sized first substrate 11 to form a first film 201 formed of the first developable composition on the surface of the first substrate 11 (FIG. 11A). The method for application here is not particularly limited, and for example, a general application method such as a spin coating method, a slit coating method, a roll coating method, a printing method, or a bar coating method can be used. In the first method, the first film 201 may be heated to remove at least part of the solvent in the first film 201. The heating temperature of the first film 201 can be appropriately set, and is preferably 60° C. or higher and 200° C. or lower, more preferably 80° C. or higher and 150° C. or lower.

The thickness of the first film 201 (the thickness of the first film 201 after heating when a heating step is provided) is, for example, 0.001 μm or more and 100 μm or less. For further suppressing deposition of foreign matter derived from a colorant, the thickness of the first film 201 is preferably 0.005 μm or more, more preferably 0.01 μm or more, still more preferably 0.1 μm or more, even more preferably 1 μm or more, particularly preferably 2 μm or more. For effectively suppressing flare and ghost by using the second layer 15 as a light-shielding partition wall, the thickness of the first film 201 is preferably 50 μm or less, more preferably 10 μm or less, still more preferably 9 μm or less, even more preferably 8 μm or less, particularly preferably 7 μm or less, and may be 6 μm or less or 5 μm or less.

Next, a second film 202 formed of the second developable composition is formed on the first film 201 by applying the second developable composition onto the first film 201 (FIG. 11B). In this way, a coating film 200 including the first film 201 and the second film 202 is formed as shown in FIG. 11B. The application method in application of the second developable composition is not particularly limited, and for example, a general application method such as a spin coating method, a slit coating method, a roll coating method, a printing method, or a bar coating method can be used. In the first method, the second film 202 may be heated to remove at least a part of the solvent in the second film 202. The temperature at which the second film 202 is heated can be appropriately set, and is preferably 60° C. or higher and 200° C. or lower, more preferably 80° C. or higher and 150° C. or lower.

The thickness of the second film 202 (the thickness of the second film 202 after heating when a heating step is provided) is, for example, 0.01 μm or more and 100 μm or less. For effectively suppressing flare and ghost by using the second layer 15 as a light-shielding partition wall, the thickness of the second film 202 is preferably 0.1 μm or more, more preferably 5 μm or more, still more preferably 10 μm or more, even more preferably 15 μm or more, particularly preferably 20 μm or more. From the viewpoint of ease of patterning of the second film 202, the thickness of the second film 202 is preferably 50 μm or less, more preferably 40 μm or less, still more preferably 30 μm or less.

For further suppressing deposition of foreign matter on the first substrate 11, it is preferable that the first film 201 covers substantially the entire surface of a region of the first substrate 11 on which the second film 202 is formed, and it is more preferable that the first film 201 covers the entire surface of a region of the first substrate 11 on which the second film 202 is formed. The phrase “the first film 201 covers substantially the entire surface” means that the first film 201 covers a 90% or more (preferably 95% or more, more preferably 98% or more), in terms of an area ratio, of a region of the first substrate 11 on which the second film 202 is formed.

The method for forming the coating film 200 in step Sa is not limited to the first method. For example, in the step Sa, the following second method may be employed. In the second method, first, the step Sa is carried out in which the first developable composition is applied onto the first substrate 11, and the first film 201 formed of the first developable composition is irradiated with an active energy ray E (see FIG. 11C) through a photomask 300 (see FIG. 11C) or without the photomask 300. When the film is irradiated with an active energy ray E through the photomask 300, a preferred range of conditions for irradiation with the active energy ray E is the same as, for example, the range in the step Sb described later. When the film is irradiated with the active energy ray E without the photomask 300, it is preferable that irradiation with the active energy ray E is performed under conditions which allow a non-exposed portion 306 (see FIG. 11C) to be removed with a developer in the step Sc described later. In the second method, the coating film 200 including the first film 201 irradiated with the active energy ray E and the second film 202 formed of the second developable composition is formed by applying the second developable composition onto the first film 201 irradiated with the active energy ray E. Except for the above (except for the points described above), the second method is the same as, for example, the first method described above.

### [Step Sb]

In the step Sb, the coating film 200 is irradiated with the active energy ray E through the photomask 300 to form an exposed portion 303 formed of the developable composition in a semi-cured state and anon-exposed portion 306 in the coating film 200 (FIG. 11C). Alight-transmitting region 300a is formed at a location corresponding to the exposed portion 303 of the photomask 300. In this way, only the coating film 200 (exposed portion 303) located below the light-transmitting region 300a is exposed, and undergoes a photocuring reaction. The exposed portion 303 in a semi-cured state includes a first semi-cured layer 301 formed of the first developable composition in a semi-cured state and a second semi-cured layer 302 formed of the second developable composition in a semi-cured state, in this order from the first substrate 11 side. The non-exposed portion 306 includes a first non-exposed layer 304 formed of the first developable composition and a second non-exposed layer 305 formed of the second developable composition, in this order from the first substrate 11 side. The integrated exposure amount during exposure is not particularly limited, and is preferably 1 mJ/cm² or more and 50,000 mJ/cm² or less, more preferably 1 mJ/cm² or more and 20,000 mJ/cm² or less. The wavelength of the active energy ray E applied in the step Sb in the range of, for example, 200 nm or more and 450 nm or less. Examples of the active energy ray E source include high pressure mercury lamps, ultra-high pressure mercury lamps, metal halide lamps, high power metal halide lamps, xenon lamps, carbon arc lamps, or light emitting diodes. The time of irradiation with the active energy ray E is preferably 1 second or more and 3,000 seconds or less, more preferably 1 second or more and 1,000 seconds or less.

After the step Sb and before the step Sc, the coating film 200 irradiated with the active energy ray E may be heated. In this case, the heating temperature can be appropriately set, and is preferably 60° C. or higher and 200° C. or lower, more preferably 80° C. or higher and 150° C. or lower.

### [Step Sc]

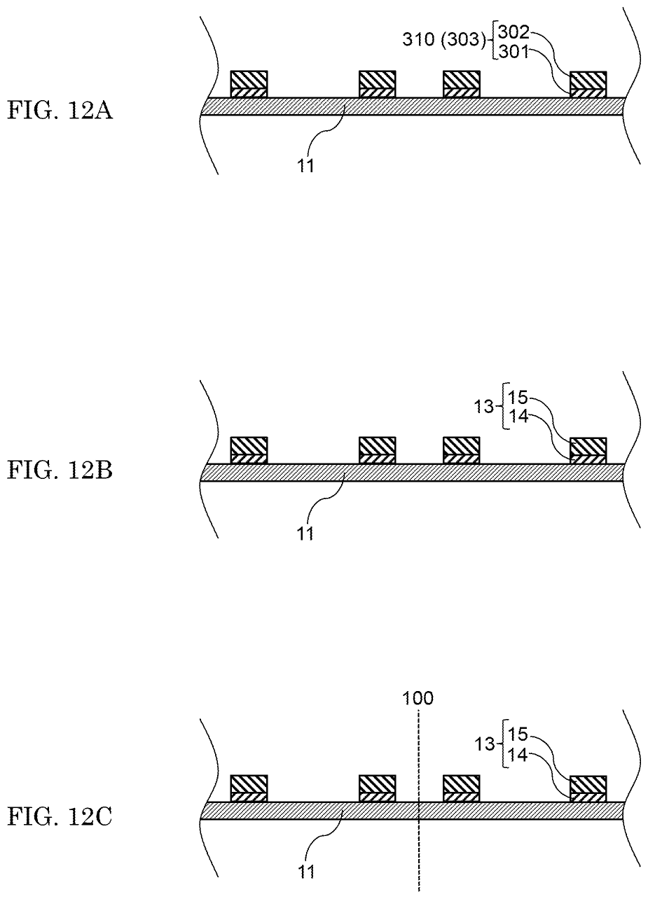

In the step Sc, a coating film patterned in a semi-cured state (pattern film 310) was formed on the first substrate 11 by removing (developing) the non-exposed portion 306 from the first substrate 11 with a developer (FIG. 12A). As the developer used in the step Sc, one or more selected from the group consisting of an alkaline developer and an organic solvent developer may be used. The developer for removing the first non-exposed layer 304 and the developer for removing the second non-exposed layer 305 may be the same or different. From the viewpoint of productivity, the developer for removing the first non-exposed layer 304 and the developer for removing the second non-exposed layer 305 are preferably the same.

The alkaline developer is, for example, an aqueous solution containing an alkali component. Examples of the alkali component include alkali organic components and alkali inorganic components. Examples of the alkali organic component include tetramethylammonium hydroxide (TMAH) and choline. Examples of the alkali inorganic component include potassium hydroxide, sodium hydroxide, potassium carbonate, sodium carbonate, and lithium carbonate. For increasing the contrast between the exposed portion 303 and the non-exposed portion 306, the concentration of the alkali component in the alkaline developer is preferably 25 mass % or less, more preferably 10 mass % or less, still more preferably 5 mass % or less. The method for removing the non-exposed portion 306 from the first substrate 11 with the alkaline developer is not particularly limited, and examples thereof include a method in which the alkaline developer is brought into contact with the coating film 200 by an immersion method, a spray method, or a paddle method to dissolve and remove the non-exposed portion 306.

As the organic solvent developer, any solvent may be used as long as it can remove the non-exposed portion 306 from the first substrate 11 while allowing the patterned exposed portion 303 (pattern film 310) to remain on the first substrate 11. Examples of the organic solvent developer include acetone, ethyl acetate, alkoxy ethanols having an alkoxy group having 1 to 4 carbon atoms, ethyl alcohol, isopropyl alcohol, butyl alcohol, diethylene glycol monomethyl ether, diethylene glycol monoethyl ether, diethylene glycol monobutyl ether, 1,1,1-trichloroethane, N-methyl-2-pyrrolidone, N,N-dimethylformamide, cyclohexanone, methyl isobutyl ketone, γ-butyrolactone, triethylene glycol dimethyl ether, and propylene glycol 1-monomethyl ether 2-acetate. To the organic solvent developer, a surfactant, an antifoaming agent, and the like may be added in a small amount, and water may be added in an amount of 1 vol % or more and 30 vol % or less for the purpose of preventing ignition. The method for removing the non-exposed portion 306 from the first substrate 11 with the organic solvent developer is not particularly limited, and examples thereof include a method in which the organic solvent developer is brought into contact with the coating film 200 by an immersion method, a spray method, or a paddle method to dissolve and remove the non-exposed portion 306.

In the step Sc, the coating film 200 may be washed with water after the developer is brought into contact with the coating film 200. When the coating film 200 is washed with water, it is preferable to remove moisture on the surface of the coating film 200 with compressed air after washing with water.

### [Step Sd1]

In the step Sd1, first, the pattern film 310 formed in the step Sc is heated to further cure the first developable composition in a semi-cured state and the second developable composition in a semi-cured state, thereby obtaining the cured product layer 13 including a cured product of the patterned coating film 200 (cured coating film 200) (FIG. 12B). The cured product layer 13 includes the first layer 14 including a cured product of the first developable composition and the second layer 15 including a cured product of a second developable composition, in this order from the first substrate 11 side. In this way, a large number of patterned cured product layers 13 are formed on the large-sized first substrate 11 as shown in FIG. 9. The temperature at which the pattern film 310 is heated in the step Sd1 is preferably 80° C. or higher and 350° C. or lower, more preferably 150° C. or higher and 250° C. or lower.

When in the step Sd1, a method is employed in which the first developable composition in a semi-cured state and the second developable composition in a semi-cured state are further cured before the first substrate 11 and the second substrate 12 are bonded (hereinafter, sometimes referred to as a “method of curing before bonding”), ingress of foreign matter can be suppressed as described above. Thus, the substrate laminate L1 obtained by the method of curing before bonding is resistant to generation of cracks by foreign matter in a thermal shock test.

When the first developable composition in a semi-cured state and the second developable composition in a semi-cured state are further cured in the step Sd1, it is possible to reduce the amount of outgas released into the hollow portion Z in bonding of the first substrate 11 and the second substrate 12 to each other. When the substrate laminate L1 forms an image sensor, the function as an image sensor may be deteriorated if the amount of outgas released into the hollow portion Z excessively increases.

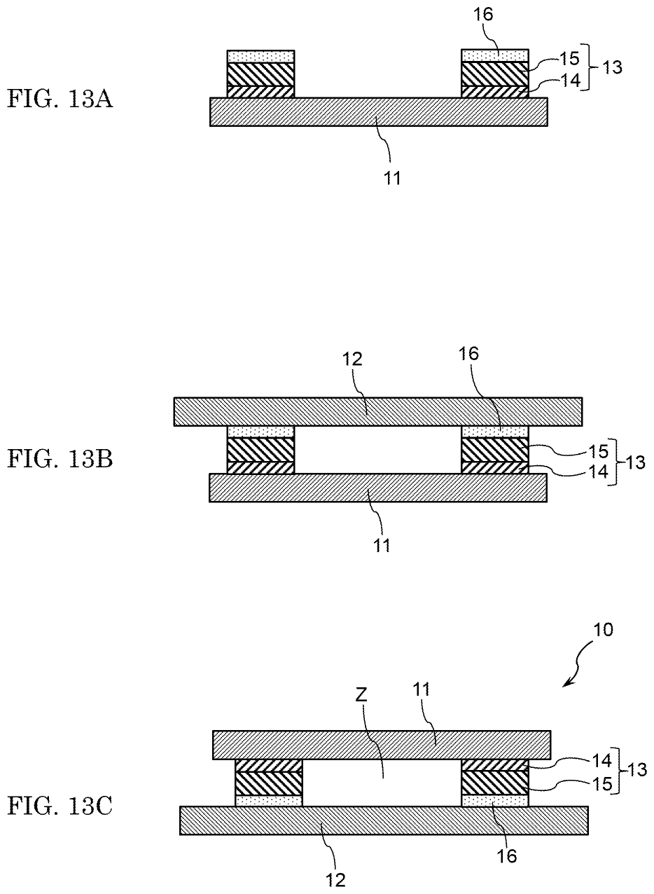

After the cured product layer 13 including a cured product pattered by the method of curing before bonding is obtained, a laminated product of the large-sized first substrate 11 and the cured product layer 13 is diced along the division line 100 in FIGS. 9 and 12C to obtain a singulated laminated product (hereinafter, sometimes referred to as a “first laminated product”) shown in FIG. 10. Subsequently, the second layer 15 of the first laminated product and the second substrate 12 are bonded with an adhesive. Specifically, first, an adhesive is applied onto the second layer 15 with a syringe or the like to form the adhesive layer 16 as shown in FIG. 13A. In the example shown in FIG. 13A, an adhesive is applied to a surface (end surface) of the second layer 15 on a side opposite to the first substrate 11 side, but the present invention is not limited thereto, and the adhesive may be applied to the second substrate 12, or the adhesive may be applied to both the second layer 15 and the second substrate 12. The method for applying the adhesive is not limited to the method using a syringe, and the adhesive may be applied by, for example, a screen printing method, a stamping method, or the like.

Subsequently, the second layer 15 and the second substrate 12 are bonded to each other with the adhesive layer 16 interposed therebetween (FIG. 13B). Subsequently, the adhesive layer 16 is cured to bond the second layer 15 and the second substrate 12, thereby obtaining the substrate laminate 10 shown in FIG. 13C. The method for curing the adhesive layer 16 may be appropriately selected according to the type of adhesive forming the adhesive layer 16. Specific examples of the method for curing the adhesive layer 16 include a method for curing by heating and a method for curing by ultraviolet irradiation.

In the method described above, the first laminated product and the second substrate 12 are bonded with an adhesive, but the present invention is not limited to this method. For example, without performing dicing in the step shown in FIG. 12C, the laminated product of the large-sized first substrate 11 and the cured product layer 13 may be bonded to the large-sized second substrate 12 with the adhesive layer 16 interposed therebetween. In this case, the singulated substrate laminate L1 are obtained by performing dicing after the laminated product and the second substrate 12 are bonded with the adhesive layer 16 interposed therebetween.

### [Another Example of Manufacturing Method M1]

Next, a method for manufacturing the substrate laminate 20 will be described as another example of the manufacturing method M1. The method for manufacturing the substrate laminate 20 is the same as the above-described manufacturing method (method for manufacturing the substrate laminate 10) in and before the step shown in FIG. 12A. Therefore, only the step subsequent to that of FIG. 12A (step Sd1) will be described below.

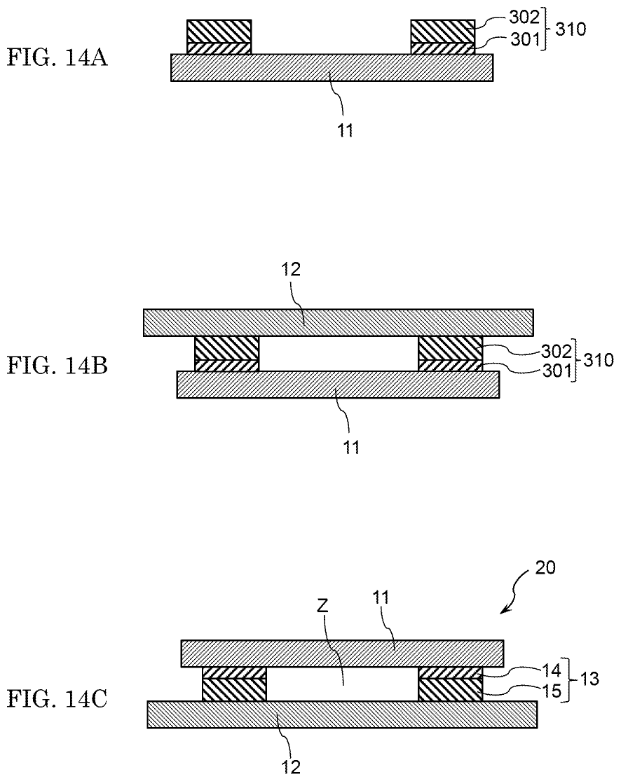

In the step Sd1 in manufacturing substrate laminate 20, first, the laminated product of the large-sized first substrate 11 and the pattern film 310, which is shown in FIG. 12A, is diced to obtain a singulated laminated product shown in FIG. 14A (hereinafter, sometimes referred to as a “second laminated product”). Next, the second substrate 12 is bonded to the second semi-cured layer 302 of the second laminated product. In this way, a laminated product is obtained in which the first substrate 11 and the second substrate 12 are laminated with the pattern film 310 interposed therebetween as shown in FIG. 14B (hereinafter, sometimes referred to as a “third laminated product”). Subsequently, the third laminated product is heated to further cure the pattern film 310 in a semi-cured state, thereby the first substrate 11 and the second substrate 12 are bonded, where the cured product layer 13 including a cured product of the pattern film 310 (patterned cured product layer 13) is interposed therebetween (FIG. 14C). In the step of heating the third laminated product, the third laminated product may be heated while being placed under a load of, for example, 0.05 MPa or more and 100 MPa or less. The temperature at which the third laminated product is heated is, for example, 60° C. or higher and 300° C. or lower. Bypassing through the above steps, the substrate laminate 20 shown in FIG. 14C is obtained.

While specific examples of the manufacturing method M1 have been described above, the method for manufacturing a substrate laminate according to the present invention is not limited to these examples. For example, in the method for manufacturing a substrate laminate according to the present invention, a second substrate having a semiconductor element substrate and a frame member may be used. In this case, for example, the above-described substrate laminate 30 (see FIG. 3), substrate laminate 40 (see FIG. 4) or substrate laminate 50 (see FIG. 5) can be manufactured by bonding the first substrate and the frame member with a pattern film interposed therebetween in the step Sd1. In the method for manufacturing a substrate laminate according to the present invention, a third film may be formed by applying a third developable composition to a surface of the second film on a side opposite to the first film side in the step Sa. In this case, the coating film that is irradiated with an active energy ray in the step Sb includes a first film, a second film and a third film in this order from the first substrate side. The thickness of the third film is, for example, 0.01 μm or more and 100 μm or less. By carrying out the step Sb, the step Sc, and the step Sd1 after formation of the coating film including the first film, the second film, and the third film, for example, the above-described substrate laminate 60 (see FIG. 6) can be manufactured.

### Fourth Embodiment: Method for Manufacturing Substrate Laminate

Next, a method for manufacturing a substrate laminate according to a fourth embodiment of the present invention (hereinafter, sometimes referred to as a “manufacturing method M2”) will be described with reference to the drawings as appropriate. The manufacturing method M2 is a suitable method for manufacturing the substrate laminate according to the second embodiment (substrate laminate L2). In the following description, descriptions of contents overlapping with those of the first embodiment, the second embodiment and the third embodiment may be omitted.

The manufacturing method M2 includes the step Sa, the step Sb, the step Sc and a step Sd2. In the step Sa, a coating film is formed on the first substrate. In the step Sb, the coating film is irradiated with an active energy ray through a photomask to form an exposed portion in a semi-cured state and a non-exposed portion on the first substrate. In the step Sc, the non-exposed portion is removed from the first substrate with a developer to form a patterned coating film (hereinafter, sometimes referred to as a “pattern film”) on the first substrate. In the step Sd2, a surface of the first substrate on a side opposite to a surface on which the pattern film is formed and the second substrate are bonded with an adhesive. The pattern film in the step Sd2 includes two types of films: a coating film patterned in a semi-cured state and a film obtained by further curing the coating film patterned in a semi-cured state (a cured product layer including a cured product of the patterned coating film).

The exposed portion in a semi-cured state, which is formed in the step Sb, includes a first semi-cured layer formed of the first developable composition in a semi-cured state and a second semi-cured layer formed of the second developable composition in a semi-cured state, in this order from the first substrate side. The first developable composition contains a polymerizable first curable compound and a first photopolymerization initiator and is free of a colorant. The second developable composition contains a polymerizable second curable compound, a second photopolymerization initiator, and a colorant.

In the manufacturing method M2, a first film formed of the first developable composition free of a colorant can be formed on the first substrate, followed by formation of a second film formed of the second developable composition containing a colorant on the first film. This enables suppression of contact between the second developable composition containing a colorant and the first substrate. Further, in the step Sc, a second non-exposed layer formed of the second developable composition containing a colorant can be removed, followed by removal of a first non-exposed layer composed of the first developable composition free of a colorant, so that it is possible to suppress the remaining of the colorant between patterns during development. For this reason, the manufacturing method M2 enables suppression of deposition of foreign matter derived from the colorant.

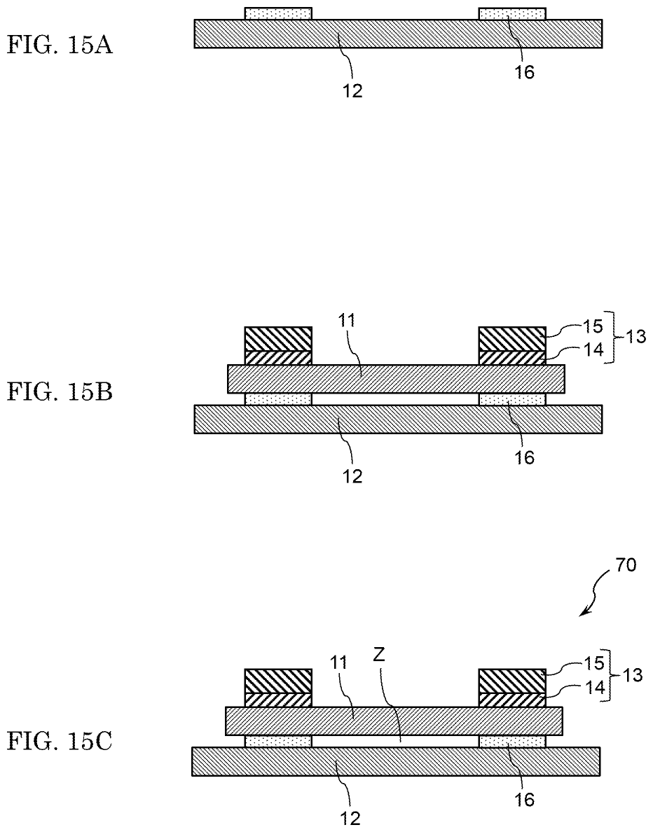

Hereinafter, each step in an example of the manufacturing method M2 will be described with reference to the drawings as appropriate. FIGS. 15A to 15C are step-by-step sectional views showing an example of the manufacturing method M2. An example of the manufacturing method M2 described below is the same as the above-described manufacturing method (method for manufacturing the substrate laminate 10) in and before the step shown in FIG. 12C. Therefore, only the step subsequent to that of FIG. 12C (step Sd2) will be described below.

In an example of the manufacturing method M2, an adhesive is applied onto the second substrate 12 with a syringe or the like to form the adhesive layer 16 as shown in FIG. 15A. In the example shown in FIG. 15A, an adhesive is applied onto the second substrate 12, but the present invention is not limited thereto, and the adhesive may be applied to the first substrate 11, or the adhesive may be applied to both the first substrate 11 and the second substrate 12. The method for applying the adhesive is not limited to the method using a syringe, and the adhesive may be applied by, for example, a screen printing method, a stamping method, or the like.

Subsequently, the first substrate 11 of the singulated laminated product (first laminated product) obtained in FIG. 12C and the second substrate 12 are bonded to each other with the adhesive layer 16 interposed therebetween (FIG. 15B). Here, a surface of the first substrate 11 on a side opposite to a surface on which the cured product layer 13 (cured product layer including a cured product of a patterned coating film) is formed and the second substrate 12 are bonded to each other. Subsequently, the adhesive layer 16 is cured to bond the first substrate 11 and the second substrate 12, thereby obtaining the substrate laminate 70 shown in FIG. 15C. The method for curing the adhesive layer 16 may be appropriately selected according to the type of adhesive forming the adhesive layer 16. Specific examples of the method for curing the adhesive layer 16 include a method for curing by heating and a method for curing by ultraviolet irradiation.

While a specific example of the manufacturing method M2 has been described above, the method for manufacturing a substrate laminate according to the present invention is not limited to the example. For example, in the step shown in FIG. 15A, a second substrate including a semiconductor element substrate and a frame member may be used. Here, a substrate laminate including alight-shielding film and a frame member is obtained by bonding the first substrate and the frame member with an adhesive in the step Sd2. In the step Sa in the manufacturing method M2, the third film may be formed by applying a third developable composition to a surface of the second film on a side opposite to the first film side. In this case, the coating film that is irradiated with an active energy ray in the step Sb includes a first film, a second film, and a third film in this order from the first substrate side. The thickness of the third film is, for example, 0.01 μm or more and 100 μm or less. By carrying out the step Sb, the step Sc, and the step Sd2 after formation of the coating film including the first film, the second film, and the third film, for example, the above-described substrate laminate 80 (see FIG. 8) can be manufactured.

Except for the above (except for the points described above), the manufacturing method M2 is as described in the section <Third embodiment: method for manufacturing substrate laminate> above.

### <Preferred Aspects of Manufacturing Methods M1 and M2>

For further suppressing flare and ghost while further suppressing deposition of foreign matter derived from a colorant, it is preferable that manufacturing methods M1 and M2 satisfy the following condition 1. For obtaining a substrate laminate which is further resistant to deposition of foreign matter derived from a colorant and further resistant to flare and ghost and which is excellent in reliability evaluated in a thermal shock test, the manufacturing methods M1 and M2 preferably satisfy the following condition 2, more preferably the following condition 3.
Condition 1: The thickness of the first film formed of the first developable composition (the thickness of the first film after heating when a heating step is provided) is 2 μm or more and 9 μm or less.
Condition 2: The condition 1 is satisfied, and the second developable composition contains, as the second curable compound, a component (A) having a plurality of cationically polymerizable groups in one molecule and a compound having one cationically polymerizable group in one molecule.
Condition 3: The condition 2 is satisfied, and the amount of the compound having one cationically polymerizable group in one molecule is 10 parts by mass or more and 30 parts by mass or less based on 100 parts by mass of the component (A) having a plurality of cationically polymerizable groups in one molecule.

### EXAMPLES

Hereinafter, the present invention will be described in more detail by way of examples, but the present invention is not limited to these examples.

### Synthesis of Curable Compound (Polysiloxane Compound)

Hereinafter, methods for synthesis of curable compounds P1 and P2 will be described. The weight average molecular weights of curable compounds P1 and P2 were calculated in terms of standard polystyrene from a chromatogram obtained by measuring the weight average molecular weight at a flow rate of 1.0 mL/min using “HLC-8420 GPC” (Column: Shodex GPC KD-806 M (2 columns) and TSKgel SuperAWM-H (2 columns)) manufactured by Tosoh Corporation, and N,N-dimethylformamide as a solvent.

### Synthesis of Curable Compound P1

143 μL of a xylene solution of a platinum vinyl siloxane complex (“Pt-VTSC-3X” manufactured by Umicore Precious Metals Japan Co., Ltd., solution with a platinum content of 3% by mass) was added to a mixture of 40 g of diallyl isocyanurate, 29 g of diallyl monomethyl isocyanurate and 264 g of 1,4-dioxane to obtain a solution S1. Meanwhile, 88 g of 1,3,5,7-tetrahydrogen-1,3,5,7-tetramethylcyclotetrasiloxane was dissolved in 176 g of toluene to obtain a solution S2.

In a nitrogen atmosphere containing 3 vol % of oxygen, the solution S1 was added dropwise to the solution S2 over 3 hours with the solution S2 heated at a temperature of 105° C. After completion of the dropwise addition, the mixture was stirred for 30 minutes while being maintained at a temperature of 105° C., thereby obtaining a solution S3. The reaction ratio of the alkenyl group of the compound contained in the obtained solution S3 was measured by ¹H-NMR, and the result showed that the reaction ratio was 95% or more.

Meanwhile, 62 g of 1-vinyl-3,4-epoxycyclohexane was dissolved in 62 g of toluene to obtain a solution S4.

In a nitrogen atmosphere containing 3 vol % of oxygen, the solution S4 was added dropwise to the solution S3 over 1 hour with the solution S3 heated at a temperature of 105° C. After completion of the dropwise addition, the mixture was stirred for 30 minutes while being maintained at a temperature of 105° C., thereby obtaining a solution S5. The reaction ratio of the alkenyl group of the compound contained in the obtained solution S5 was measured by ¹H-NMR, and the result showed that the reaction ratio was 95% or more.

Subsequently, the solution S5 was cooled, and the solvent (toluene, xylene and 1,4-dioxane) was then distilled off from the solution S5 under reduced pressure to obtain a solid. Propylene glycol 1-monomethyl ether 2-acetate (hereinafter, referred to as “PGMEA”) was added to the obtained solid to obtain a solution SP1 containing the curable compound P1 (concentration of the curable compound P1: 70 mass %). The curable compound P1 was a polysiloxane compound having a plurality of cationically polymerizable groups (specifically, alicyclic epoxy groups) and a plurality of alkali-soluble groups (specifically, X2 groups) in one molecule, and a cyclic polysiloxane structure in the main chain (a polymer having a weight average molecular weight of 30,000).

### Synthesis of Curable Compound P2

Except that 62 g of allyl acrylate was used instead of 62 g of 1-vinyl-3,4-epoxycyclohexane, the same procedure as in [Synthesis of curable compound P1] above was carried out to obtain a solution SP2 containing a curable compound P2 (concentration of the curable compound P2: 70 mass %). The curable compound P2 was a polysiloxane compound having a plurality of radically polymerizable groups (specifically, acryloyl groups) and a plurality of alkali-soluble groups (specifically, X2 groups) in one molecule, and a cyclic polysiloxane structure in the main chain (a polymer having a weight average molecular weight of 28,000).

### Preparation of Other Materials

As materials for developable compositions, the following materials were prepared in addition to the solution SP1, the solution SP2, and PGMEA.
3′,4′-Epoxycyclohexylmethyl 3,4-epoxycyclohexanecarboxylate (“CELLOXIDE (registered trademark) 2021P” manufactured by DAICEL CORPORATION, hereinafter referred to as “2021P”) as a curable compound having two alicyclic epoxy groups in one molecule.
Di-2-ethylhexyl 4,5-epoxycyclohexane-1,2-dicarboxylate (“SANSO CIZER (registered trademark) E-PS” manufactured by New Japan Chemical Co., Ltd. (hereinafter referred to as “E-PS”) as a curable compound having one alicyclic epoxy group in one molecule.
Trimethylolpropane triacrylate (“A-TMPT” manufactured by Shin-Nakamura Chemical Co., Ltd., hereinafter referred to as “A-TMPT”) as a curable compound having three acryloyl groups in one molecule.
A photocationic polymerization initiator having a naphthalimide structure (“SP-606” manufactured by ADEKA Corporation, hereinafter referred to as “SP-606”).
A sulfonium salt-based compound (“CPI-210S” manufactured by San-Apro Ltd, hereinafter referred to as “CPI-210S”) as a photocationic polymerization initiator.
9,10 dipropoxyanthracene (manufactured by Kawasaki Kasei Chemicals Ltd., hereinafter referred to as “9,10 DPA”) as a sensitizer.
An epoxy acrylate-based compound having an acidic group (“KAYARAD (registered trademark) CCR-12911H” manufactured by Nippon Kayaku Co., Ltd., hereinafter referred to as “1291H”).
An oxime ester-based compound (“Irgacure (registered trademark) OXE02” manufactured by BASF Japan Ltd., hereinafter referred to as “OXE02”) as a photoradical polymerization initiator.
Carbon black (“MA100” manufactured by Mitsubishi Chemical Corporation, hereinafter referred to as “MA100”) as a colorant.

### Preparation of Developable Composition

The materials shown in Tables 1 and 2 were blended in the blending amounts shown in Tables 1 and 2, thereby obtaining developable compositions DP1 to DP15 for use in examples and comparative examples. The curable compounds P1 and P2 were blended in the form of solutions SP1 and SP2, respectively. In Tables 1 and 2, the blending amount of PGMEA in each of the developable compositions DP1 to DP4, DP6 to DP11 and DP13 to DP15 also includes the amount of PGMEA in the solution SP1 or SP2. In Tables 1 and 2, “P1” and “P2” mean the curable compound P1 and the curable compound P2, respectively. In Tables 1 and 2, “-” means that the relevant material was not blended.

TABLE 1

| Developable composition | | DP1 | DP2 | DP3 | DP4 | DP5 | DP6 | DP7 | DP8 | DP9 |
|---|---|---|---|---|---|---|---|---|---|---|
| Blending amount | P1 | 100 | — | 100 | 100 | — | 100 | — | 100 | 100 |
| of each | P2 | — | 100 | — | — | — | — | 100 | — | — |
| material | 2021P | 15 | — | 15 | 15 | — | 15 | — | 15 | 15 |
| (unit: parts | E-PS | — | — | — | — | — | — | — | — | — |
| by mass) | A-TMPT | — | — | — | — | 50 | — | — | — | — |
| | SP-606 | 3 | — | — | 3 | — | 3 | — | 3 | 3 |
| | CPI-210S | — | — | 3 | — | — | — | — | — | — |
| | 9,10-DPA | 1.5 | 1.5 | 1.5 | — | 1.5 | 1.5 | 1.5 | 1.5 | 1.5 |
| | 1291H | — | — | — | — | 50 | — | — | — | — |
| | OXE02 | — | 1 | — | — | 1 | — | 1 | — | — |
| | MA100 | — | — | — | — | — | 3 | 3 | 15 | 0.01 |
| | PGMEA | 35 | 35 | 35 | 35 | 35 | 35 | 35 | 35 | 35 |

TABLE 2

| Developable composition | | DP10 | DP11 | DP12 | DP13 | DP14 | DP15 |
|---|---|---|---|---|---|---|---|
| Blending amount | P1 | 100 | 100 | — | 100 | 100 | — |
| of each | P2 | — | — | — | — | — | 100 |
| material | 2021P | 15 | 15 | — | — | 15 | — |
| (unit: parts | E-PS | — | — | — | 20 | — | — |
| by mass) | A-TMPT | — | — | 50 | — | — | — |
| | SP-606 | — | 3 | — | 3 | — | — |
| | CPI-210S | 3 | — | — | — | 1.5 | — |
| | 9,10-DPA | 1.5 | — | 1.5 | 1.5 | — | — |
| | 1291H | — | — | 50 | — | — | — |
| | OXE02 | — | — | 1 | — | — | 1 |
| | MA100 | 3 | 3 | 3 | 3 | — | — |
| | PGMEA | 35 | 35 | 35 | 35 | 35 | 35 |

### Production of Substrate Laminate

Hereinafter, methods for producing a substrate laminate (specifically, a hollow structure having a sealed hollow portion) of each of Examples 1 to 15 and Comparative Examples 1 to 11 will be described.

### Example 1

### Production of Sample 1

The developable composition DP1 as a first developable composition was applied onto a glass substrate as a first substrate by a spin coater to obtain a first laminate in which a first film formed of the developable composition DP1 was formed on a glass substrate. Subsequently, the first laminate was heated for 5 minutes on a hot plate heated to a temperature of 120° C. Subsequently, the developable composition DP6 as a second developable composition was applied onto the heated first film by a spin coater to form a second film formed of the developable composition DP6 on the first film. In this way, a second laminate was obtained in which a first film and a second film were formed in this order on a glass substrate. Subsequently, a coating film including a first film (thickness: 4 μm) and a second film (thickness: 20 μm) was formed on a glass substrate by heating the second laminate for 5 minutes on a hot plate heated to a temperature of 120° C.

Subsequently, through a photomask (longitudinal direction: line/space=50 μm/50 μm, lateral direction: line/space=100 μm/100 μm) in which a line pattern is formed in a grid shape, the coating film of the heated second laminate was irradiated with light under the condition of an integrated exposure amount of 10,000 mJ/cm² using a manual exposure machine (“MA-1300” manufactured by Japan Science Engineering Co., Ltd., lamp: high-pressure mercury lamp). In this way, the coating film was exposed (specifically, soft contact exposure).

Subsequently, the exposed second laminate was heated for 10 minutes on a hot plate heated to a temperature of 120° C. Subsequently, the heated second laminate was allowed to stand in an atmosphere at a temperature of 25° C. for 1 minute, and then immersed in a TMAH aqueous solution (concentration of TMAH: 2.38 mass %) as an alkaline developer for 60 seconds. Subsequently, the second laminate which had been immersed in the alkaline developer was washed with water for 30 seconds, and moisture on the surface was then removed with compressed air. In this way, a coating film in a semi-cured state with a grid-shaped pattern (pattern film) was formed.

Subsequently, on a hot plate heated to a temperature of 230° C., the second laminate free of moisture was heated for 30 minutes to cure the pattern film (exposed portion), thereby obtaining a sample 1 including a cured product layer patterned on a glass substrate (a layer in which a coating film patterned into a grid shape is cured). The cured product layer included a first layer (thickness: 4 μm) formed of a cured product of the developable composition DP1 and a second layer (thickness: 20 μm) formed of a cured product of the developable composition DP6, in this order from the glass substrate side.

### Production of Sample 2

The sample 1 was cut with a dicing apparatus to obtain a singulated sample 2 with a size of 12 mm×12 mm. The sample 2 is a sample obtained by singulating the sample 1.

### Production of Substrate Laminate

The sample 2 and a silicon wafer (size: 12 mm×12 mm) as a second substrate were laminated with an epoxy-based adhesive interposed therebetween, thereby obtaining a third laminate. The lamination was performed so as to interpose the epoxy-based adhesive between the cured product layer and the silicon wafer. The epoxy-based adhesive used was a thermosetting adhesive containing bisphenol A diglycidyl ether as a main agent, and an imidazole-based curing agent as a curing agent, where the mass ratio of the main agent to the curing agent (main agent/curing agent) is 100/3.

Subsequently, the third laminate was heated in an oven at a temperature of 200° C. for 2 hours to obtain a substrate laminate of Example 1. The substrate laminate of Example 1 had a structure in which a glass substrate, a cured product layer, an adhesive layer including a cured product of an adhesive (thickness: 100 μm), and a silicon wafer were laminated in this order.

### Examples 2 to 8

Substrate laminates of Examples 2 to 8 were each produced in the same manner as in Example 1 except that developable compositions shown in Table 3 below were used as the first developable composition and the second developable composition.

### Example 9

A substrate laminate of Example 9 was produced in the same manner as in Example 1 except that an organic solvent developer (PGMEA) was used instead of the alkaline developer.

### Example 10

A substrate laminate of Example 10 was produced in the same manner as in Example 1 except that after formation of the first film and the second film on the glass substrate and before exposure, the following third film forming step was carried out.

### (Third Film Forming Step)

The developable composition DP14 as a third developable composition was applied onto the second film by a spin coater to form a third film formed of the developable composition DP14 on the second film. Subsequently, a coating film including a first film (thickness: 4 μm), a second film (thickness: 20 μm) and a third film (thickness: 46 μm) was formed on a glass substrate by heating the obtained laminated product for 5 minutes on a hot plate heated to a temperature of 120° C.

### Example 11

A substrate laminate of Example 11 was produced in the same manner as in Example 10 except that the developable composition DP15 was used instead of the developable composition DP14.

### Examples 12 to 15

Substrate laminates of Examples 12 to 15 were each produced in the same manner as in Example 1 except that the amount of application of the first developable composition was adjusted so that the thickness of the first film in the second laminate after heating and before exposure coincided with the thickness described in Table 4 below.

### Comparative Example 1

A substrate laminate of Comparative Example 1 was produced in the same manner as in Example 1 except that the second film was directly formed on a glass substrate without forming the first film.

### Comparative Examples 2 to 8

Substrate laminates of Comparative Examples 2 to 8 were each produced in the same manner as in Comparative Example 1 except that developable compositions shown in Tables 5 and 6 below were used as the second developable composition.

### Comparative Example 9

A substrate laminate of Comparative Example 9 was produced in the same manner as in Comparative Example 1 except that an organic solvent developer (PGMEA) was used instead of the alkaline developer.

### Comparative Example 10

A substrate laminate of Comparative Example 10 was produced in the same manner as in Comparative Example 1 except that after formation of the second film on the glass substrate and before exposure, the following third film forming step was carried out.

(Third Film Forming Step) The developable composition DP14 as a third developable composition was applied onto the second film by a spin coater to form a third film formed of the developable composition DP14 on the second film. Subsequently, a coating film including a second film (thickness: 20 μm) and a third film (thickness: 46 μm) was formed on a glass substrate by heating the obtained laminated product for 5 minutes on a hot plate heated to a temperature of 120° C.

### Comparative Example 11

A substrate laminate of Comparative Example 11 was produced in the same manner as in Comparative Example 10 except that the developable composition DP15 was used instead of the developable composition DP14.

### <Method for Measuring and Evaluating Physical Properties>

Next, methods for measuring and evaluating various physical properties will be described.

### [Existence or Non-Existence of Foreign Matter]

Using a 3D measurement laser microscope (“LEXT (registered trademark) OLS 4000” manufactured by Olympus Corporation), spaces between the patterns of the cured product layer of the sample 2 were observed at a magnification of 100 times, and existence or non-existence of foreign matter derived from a colorant in a space portion of a pattern region with a line/space of 50 μm/50 μm was examined. The existence or non-existence of foreign matter was determined on the basis of the following criteria. When the criterion A or B was met, it was evaluated that “deposition of foreign matter derived from a colorant was suppressed.” On the other hand, when the criterion C was met, it was evaluated that “deposition of foreign matter derived from a colorant was not suppressed.”
A: Foreign matter having a maximum diameter of 25 μm or more was not observed.
B: Foreign matter having a maximum diameter of 25 μm or more were confirmed, but the number of the foreign matters was 5 or less.
C: The number of foreign matters having a maximum diameter of 25 μm or more was 6.

### [Patterning Property]

The pattern shape of the pattern film of the sample 1 was observed with a 3D measurement laser microscope (“LEXT (registered trademark) OLS4000” manufactured by Olympus Corporation) and a stylus type surface profile measuring instrument (“Dektak (registered trademark) 150” manufactured by Veeco Instruments Inc.), and evaluated in accordance with the following criteria.
A: Either a residue or peeling did not occur in the pattern region with a line/space of 50 μm/50 μm.
B: One of a residue and peeling occurred in the pattern region with a line/space of 50 μm/50 μm, but either a residue or peeling did not occur in the pattern region with a line/space of 100 μm/100 μm.
C: Cases that do not comply with either A or B above.

### [Optical Density]

The optical density (OD) of the sample 1 was measured using a transmission densitometer (“361T” manufactured by X-rite, Inc.). In Examples 1, 2 and 5 to 15 and Comparative Examples 1, 2 and 5 to 11, the optical density was 2.7. In Example 3 and Comparative Example 3, the optical density was 4.0. In Example 4 and Comparative Example 4, the optical density was 0.5.

### [Die Shear Strength]

A shear force was applied to the substrate laminate (specifically, a shear force was applied to the glass substrate and the silicon wafer) using a die shear tester (“SERIES 4000” manufactured by Nordson DAGE), and a load under which the silicon wafer was peeled from the substrate laminate was measured. The maximum value of the load was defined as a die shear strength. The die shear strength was measured under the conditions of a shear height of 50 μm and a shear speed of 80 μm/sec in accordance with MIL STD 883.

### [Thermal Shock Test 1 (Thermal Shock Test of Sample 2)]

For each of examples and comparative examples, five samples 2 for production of substrate laminates were prepared, and each subjected to a thermal shock test using a heat shock testing apparatus (“ES-57L” manufactured by Hitachi Global Life Solutions, Inc.). In the thermal shock test, an operation in which the sample 2 is held in an atmosphere at −55° C. for 30 minutes and then in an atmosphere at 125° C. for 30 minutes was carried out 1,000 times. At the end of 500 cycles and at the end of 1,000 cycles, the sample 2 was observed on the glass substrate side with an optical microscope, and evaluated in accordance with the following criteria. As compared to a thermal shock test of the substrate laminate (thermal shock test 2) as described later, the thermal shock test of the sample 2 (thermal shock test 1) shows an apparent difference in thermal expansion coefficient between the glass substrate and the cured product layer, and therefore enables evaluation under severer conditions.
A: A defect (either cracking or peeling) was not observed in any of five samples 2 at the end of 500 cycles and at the end of 1,000 cycles.
B: A defect (at least one of cracking and peeling) was observed in any of five samples 2 at the end of 1,000 cycles, but a defect (either cracking or peeling) was not observed in any of five samples 2 at the end of 500 cycles.
C: Cases that do not comply with either A or B above.

### [Thermal Shock Test 2 (Thermal Shock Test of Substrate Laminate)]

For each of examples and comparative examples, five substrate laminates were prepared, and each subjected to a thermal shock test using a heat shock testing apparatus (“ES-57L” manufactured by Hitachi Global Life Solutions, Inc.). In the thermal shock test, an operation in which the substrate laminate is held in an atmosphere at −55° C. for 30 minutes and then in an atmosphere at 125° C. for 30 minutes was carried out 2,000 times. At the end of 1,000 cycles and at the end of 2,000 cycles, the substrate laminate was observed on the glass substrate side with an optical microscope, and evaluated in accordance with the following criteria.
A: A defect (either cracking or peeling) was not observed in any of five substrate laminates at the end of 1,000 cycles and at the end of 2,000 cycles.
B: A defect (at least one of cracking and peeling) was observed in any of five substrate laminates at the end of 2,000 cycles, but a defect (either cracking or peeling) was not observed in any of five substrate laminates at the end of 1,000 cycles.
C: Cases that do not comply with either A or B above.

### [Bearing Glare Index]

A camera module was produced using the sample 2, an image sensor substrate, and an epoxy-based adhesive. The epoxy-based adhesive used was a thermosetting adhesive containing bisphenol A diglycidyl ether as a main agent, and an imidazole-based curing agent as a curing agent, where the mass ratio of the main agent to the curing agent (main agent/curing agent) is 100/3. With the obtained camera module as a measurement sample, the veiling glare index was measured using a veiling glare evaluation apparatus (“LFM-1000” manufactured by TSUBOSAKA ELECTRIC Co., Ltd.). The veiling glare index (unit:%) is obtained from the equation “veiling glare index=100×luminance of black body/luminance of white body.” A veiling glare index obtained using a veiling glare evaluation apparatus (“LFM-1000” manufactured by TSUBOSAKA ELECTRIC Co., Ltd.) for the following reference sample was defined as 100%, and the veiling glare index of the measurement sample was normalized. The normalized value (hereinafter, referred to as a “normalized BG index”) was used as an index of ability to suppress occurrence of flare. It was determined that the smaller the normalized BG index, the higher the ability to suppress occurrence of flare. The normalized BG index is preferably 95% or less, more preferably 90% or less, still more preferably 88% or less.

### Reference Sample

A camera module was produced in the same manner as in the method for manufacturing the measurement sample except that a glass substrate was used instead of the sample 2, and the camera module was used as a reference sample.

For each of Examples 1 to 15 and Comparative Examples 1 to 11, the type of the first developable composition, the type of the second developable composition, the type of the third developable composition, the thickness of the first film, the type of the developer, the existence or non-existence of foreign matter, the patterning property, the die shear strength, the result of evaluation in the thermal shock test 1, the result of evaluation in the thermal shock test 2, and the normalized BG index are shown in Tables 3 to 6. In Tables 5 and 6, “-” in the column of the type of the first developable composition means that the first film was not formed. In Tables 3 to 6, “-” in the column of the type of the third developable composition means that the third film was not formed. In Tables 3 to 6, “ALK” means an alkaline developer. In Tables 4 and 6, “ORG” means an organic solvent developer.

TABLE 3

| EXAMPLES | 1 | 2 | 3 | 4 | 5 | 6 | 7 | 8 |
|---|---|---|---|---|---|---|---|---|
| Type of first developable composition | DP1 | DP2 | DP1 | DP1 | DP3 | DP4 | DP5 | DP1 |
| Type of second developable composition | DP6 | DP7 | DP8 | DP9 | DP10 | DP11 | DP12 | DP13 |
| Type of third developable composition | — | — | — | — | — | — | — | — |
| Thickness of first film [μm] | 4 | 4 | 4 | 4 | 4 | 4 | 4 | 4 |
| Type of developer | ALK | ALK | ALK | ALK | ALK | ALK | ALK | ALK |
| Existence or non-existence | A | A | B | A | A | A | A | A |
| of foreign matter | | | | | | | | |
| Patterning property | A | A | A | A | B | B | B | A |
| Die shear strength [kgf] | 30 | 30 | 15 | 30 | 30 | 30 | 10 | 30 |
| Thermal shock test 1 | B | B | B | B | B | B | B | A |
| Thermal shock test 2 | A | A | B | A | A | A | B | A |
| Normalized BG index [%] | 88 | 88 | 85 | 98 | 88 | 88 | 88 | 88 |

TABLE 4

| EXAMPLES | 9 | 10 | 11 | 12 | 13 | 14 | 15 |
|---|---|---|---|---|---|---|---|
| Type of first developable composition | DP1 | DP1 | DP2 | DP1 | DP1 | DP1 | DP1 |
| Type of second developable composition | DP6 | DP6 | DP7 | DP6 | DP6 | DP6 | DP6 |
| Type of third developable composition | — | DP14 | DP15 | — | — | — | — |
| Thickness of first film [μm] | 4 | 4 | 4 | 1 | 2 | 6 | 10 |
| Type of developer | ORG | ALK | ALK | ALK | ALK | ALK | ALK |
| Existence or non-existence | A | A | A | B | A | A | A |
| of foreign matter | | | | | | | |
| Patterning property | C | A | A | A | A | A | A |
| Die shear strength [kgf] | 30 | 30 | 30 | 30 | 30 | 30 | 30 |
| Thermal shock test 1 | B | B | B | B | B | B | B |
| Thermal shock test 2 | A | A | A | A | A | A | A |
| Normalized BG index [%] | 88 | 88 | 88 | 88 | 88 | 90 | 95 |

TABLE 5

| Comparative Example | 1 | 2 | 3 | 4 | 5 | 6 |
|---|---|---|---|---|---|---|
| Type of first developable composition | — | — | — | — | — | — |
| Type of second developable composition | DP6 | DP7 | DP8 | DP9 | DP10 | DP11 |
| Type of third developable composition | — | — | — | — | — | — |
| Type of developer | ALK | ALK | ALK | ALK | ALK | ALK |
| Existence or non-existence | C | C | C | C | C | C |
| of foreign matter | | | | | | |
| Patterning property | A | A | A | A | B | B |
| Die shear strength [kgf] | 30 | 30 | 15 | 30 | 30 | 30 |
| Thermal shock test 1 | B | B | B | B | B | B |
| Thermal shock test 2 | A | A | B | A | A | A |
| Normalized BG index [%] | 88 | 88 | 85 | 98 | 88 | 88 |

TABLE 6

| Comparative Example | 7 | 8 | 9 | 10 | 11 |
|---|---|---|---|---|---|
| Type of first | — | — | — | — | — |
| developable composition | | | | | |
| Type of second | DP12 | DP13 | DP6 | DP6 | DP7 |
| developable composition | | | | | |
| Type of third | — | — | — | DP14 | DP15 |
| developable composition | | | | | |
| Type of developer | ALK | ALK | ORG | ALK | ALK |
| Existence or non-existence | C | C | C | C | C |
| of foreign matter | | | | | |
| Patterning property | B | A | C | A | A |
| Die shear strength [kgf] | 10 | 30 | 30 | 30 | 30 |
| Thermal shock test 1 | B | A | B | B | B |
| Thermal shock test 2 | B | A | A | A | A |
| Normalized BG index [%] | 88 | 88 | 88 | 88 | 88 |

In the substrate laminates of Examples 1 to 15, the cured product layer included a first layer including a cured product of a developable composition free of a colorant and a second layer including a cured product of a developable composition containing a colorant, in this order from the glass substrate side. As shown in Tables 3 and 4, the result of evaluation of existence or non-existence of foreign matter met the criterion A or B in Examples 1 to 15. Therefore, in Examples 1 to 15, deposition of foreign matter derived from a colorant was suppressed.

In the substrate laminates of Comparative Examples 1 to 11, a layer including a cured product of a developable composition containing a colorant was directly formed on a glass substrate. As shown in Tables 5 and 6, the result of evaluation of existence or non-existence of foreign matter met the criterion C in Comparative Examples 1 to 11. Thus, in Comparative Examples 1 to 11, deposition of foreign matter derived from a colorant was not suppressed.

The above results show that the present invention can provide a substrate laminate resistant to deposition of foreign matter derived from a colorant.

DESCRIPTION OF REFERENCE CHARACTERS

| | |
|---|---|
| 10, 20, 30, 40, 50, 60, 70, 80 | substrate laminate |
| 11 | first substrate |
| 12 | second substrate |
| 13 | cured product layer |
| 14 | first layer |
| 15 | second layer |
| 16 | adhesive layer |
| 31 | semiconductor element substrate |
| 32 | frame member |
| 200 | coating film |
| 201 | first film |
| 202 | second film |
| 300 | photomask |
| 301 | first semi-cured layer |
| 302 | second semi-cured layer |
| 303 | exposed portion |
| 306 | non-exposed portion |

1. A method for manufacturing a substrate laminate, comprising:
a step Sa of forming a coating film on a first substrate;
a step Sb of forming an exposed portion in a semi-cured state and a non-exposed portion on the first substrate by irradiating the coating film with an active energy ray through a photomask;
a step Sc of forming a patterned coating film on the first substrate by removing the non-exposed portion from the first substrate with a developer; and
a step Sd1 of bonding the first substrate and a second substrate with the patterned coating film interposed therebetween, wherein
the exposed portion in the semi-cured state includes a first semi-cured layer formed of a first developable composition in a semi-cured state and a second semi-cured layer formed of a second developable composition in a semi-cured state, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

2. The method for manufacturing a substrate laminate according to claim 1, wherein
the second substrate includes a semiconductor element substrate and a frame member, and
the first substrate and the frame member are bonded with the patterned coating film interposed therebetween in the step Sd1.

3. The method for manufacturing a substrate laminate according to claim 1 or 2, wherein in the step Sd1, the patterned coating film is heated to further cure the first developable composition in the semi-cured state and the second developable composition in the semi-cured state, and the cured coating film and the second substrate are then bonded with an adhesive.

4. The method for manufacturing a substrate laminate according to claim 1 or 2, wherein in the step Sd1, a laminated product is formed by laminating the first substrate and the second substrate with the coating film, which is patterned in a semi-cured state, interposed therebetween, and the first substrate and the second substrate are then bonded by heating the laminated product to further cure the coating film.

5. A method for manufacturing a substrate laminate, comprising:
a step Sa of forming a coating film on a first substrate;
a step Sb of forming an exposed portion in a semi-cured state and a non-exposed portion on the first substrate by irradiating the coating film with an active energy ray through a photomask;
a step Sc of forming a patterned coating film on the first substrate by removing the non-exposed portion from the first substrate with a developer; and
a step Sd2 of bonding a surface of the first substrate on a side opposite to a surface on which the patterned coating film is formed and a second substrate with an adhesive, wherein
the exposed portion in the semi-cured state includes a first semi-cured layer formed of a first developable composition in a semi-cured state and a second semi-cured layer formed of a second developable composition in a semi-cured state, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

6. The method for manufacturing a substrate laminate according to claim 5, wherein
the second substrate includes a semiconductor element substrate and a frame member, and
the first substrate and the frame member are bonded with the adhesive in the step Sd2.

7. The method for manufacturing a substrate laminate according to claim 1 or 5, wherein in the step Sa, the first developable composition is applied onto the first substrate, and the second developable composition is applied onto a first film formed of the first developable composition to form the coating film including the first film and a second film formed of the second developable composition.

8. The method for manufacturing a substrate laminate according to claim 7, wherein
the coating film further includes a third film composed of a third developable composition,
the third developable composition contains a polymerizable third curable compound and a third photopolymerization initiator and is free of a colorant, and
the third developable composition is applied to a surface of the second film on a side opposite to a first film side in the step Sa.

9. The method for manufacturing a substrate laminate according to claim 1 or 5, wherein in the step Sa, the first developable composition is applied onto the first substrate, a first film composed of the first developable composition is irradiated with an active energy ray, and the second developable composition is applied onto the first film after irradiation with the active energy ray to form the coating film including the first film and a second film formed of the second developable composition.

10. The method for manufacturing a substrate laminate according to claim 9, wherein
the coating film further includes a third film composed of a third developable composition,
the third developable composition contains a polymerizable third curable compound and a third photopolymerization initiator and is free of a colorant, and
the third developable composition is applied to a surface of the second film on a side opposite to a first film side in the step Sa.

11. The method for manufacturing a substrate laminate according to claim 1 or 5, wherein
the first developable composition and the second developable composition are alkali-soluble, and
at least one of the first curable compound and the second curable compound is cationically polymerizable or radically polymerizable.

12. The method for manufacturing a substrate laminate according to claim 1 or 5, wherein
the second photopolymerization initiator is a photocationic polymerization initiator, and
the photocationic polymerization initiator has one or more structures selected from the group consisting of a naphthalimide structure and an oxime sulfonate structure.

13. A substrate laminate comprising a first substrate, a second substrate, and a cured product layer interposed between the first substrate and the second substrate, wherein
the cured product layer is patterned, and includes a first layer including a cured product of a first developable composition and a second layer including a cured product of a second developable composition, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

14. The substrate laminate according to claim 13, further comprising an adhesive layer that bonds the cured product layer and the second substrate.

15. A substrate laminate comprising a first substrate, a second substrate, an adhesive layer that bonds the first substrate and the second substrate, and a cured product layer disposed on a surface of the first substrate on a side opposite to a second substrate side, wherein
the cured product layer is patterned, and includes a first layer including a cured product of a first developable composition and a second layer including a cured product of a second developable composition, in this order from a first substrate side,
the first developable composition contains a polymerizable first curable compound and a first photopolymerization initiator and is free of a colorant, and
the second developable composition contains a polymerizable second curable compound, a second photopolymerization initiator, and a colorant.

16. An image sensor comprising the substrate laminate according to claim 13 or 15.
